(19) United States
(12) Patent Application Publication
(10) Pub. No.: US 2025/0070019 A1
(43) Pub. Date: Feb. 27, 2025

(54) INTEGRATED CIRCUIT INCLUDING ELECTRONIC FUSE BIT CELL

(71) Applicant: SAMSUNG ELECTRONICS CO., LTD., Suwon-si (KR)

(72) Inventors: Minjeung Kang, Suwon-si (KR); Hyojoon An, Suwon-si (KR)

(21) Appl. No.: 18/753,168

(22) Filed: Jun. 25, 2024

(30) Foreign Application Priority Data
Aug. 24, 2023 (KR) 10-2023-0111520
Dec. 19, 2023 (KR) 10-2023-0186153

(51) Int. Cl. H01L 23/525; G11C 17/16; G11C 17/18; H01L 23/528

(52) U.S. Cl. CPC H01L 23/5256; H01L 23/5286; G11C 17/16; G11C 17/18

(57) ABSTRACT

An integrated circuit includes a first backside wiring layer arranged on a backside of a substrate, and an e-fuse bit cell. The e-fuse bit cell includes an e-fuse, a transistor arranged on a front side of the substrate, and a first backside contact passing through the substrate in a vertical direction and electrically connecting the e-fuse to the transistor. The e-fuse includes a first terminal electrically connected to a bit line, a second terminal electrically connected to the first backside contact, and a link between the first terminal and the second terminal, and the first terminal, the second terminal, and the link are included in the first backside wiring layer.

### CROSS-REFERENCE TO RELATED APPLICATIONS

This application claims priority under 35 U.S.C. § 119 to Korean Patent Application Nos. 10-2023-0111520, filed on Aug. 24, 2023, and 10-2023-0186153, filed on Dec. 19, 2023, in the Korean Intellectual Property Office, the disclosures of which are incorporated by reference herein in their entirety.

### BACKGROUND

Due to the demand for highly integrated semiconductor devices and the development of semiconductor processes, widths, pitches, and/or heights of wirings included in an integrated circuit may be reduced, and parasitic elements of the wirings may be increased. Also, to reduce power consumption and increase an operating speed, a power supply voltage of an integrated circuit may be reduced, and thus, the influence of the parasitic elements of the wirings upon the integrated circuit may be further increased. Accordingly, demand for a method of designing an integrated circuit that effectively routes wirings and vias has been increasing.

### SUMMARY

In general, in some aspects, the present disclosure is directed toward an integrated circuit capable of improving a power performance area (PPA) by implementing an electronic fuse (e-fuse) bit cell by utilizing a front side wiring layer and a backside wiring layer, and a method of designing the integrated circuit.

According to some aspects, the present disclosure is directed to an integrated circuit including a first backside wiring layer arranged on a backside of a substrate, and an e-fuse bit cell including an e-fuse, a transistor arranged on a front surface of the substrate, a first backside contact that passes through the substrate in a vertical direction so as to electrically connect the e-fuse to the transistor, wherein the e-fuse includes a first terminal electrically connected to a bit line, a second terminal electrically connected to the first backside contact, and a link between the first terminal and the second terminal, and the first terminal, the second terminal, and the link are included in the first backside wiring layer.

According to some aspects, the present disclosure is directed to an integrated circuit including a first front side wiring layer arranged above a front side of a substrate, a backside wiring layer arranged on a backside of the substrate and including a first backside pattern, a first through-via arranged on the first backside pattern and passing through the substrate in a vertical direction, and an e-fuse bit cell including an e-fuse and a transistor arranged on the front side of the substrate, wherein the e-fuse includes a first terminal electrically connected to the first through-via and electrically connected to a bit line via the first through-via and the first backside pattern, the second terminal electrically connected to the transistor, and a link between the first terminal and the second terminal, and the first terminal, the second terminal, and the link are included in the first front side wiring layer.

According to some aspects, the present disclosure is directed to an integrated circuit including a first front side wiring layer arranged above a front side of a substrate, a second front side wiring layer arranged above the first front side wiring layer, a backside wiring layer arranged on a backside of the substrate and configured to receive a supply voltage, and an e-fuse bit cell including an e-fuse and a transistor arranged on the front side of the substrate, wherein the e-fuse includes a first terminal electrically connected to a bit line, a second terminal electrically connected to a drain of the transistor, and a link between the first terminal and the second terminal, the first terminal, the second terminal, and the link are included in the second front side wiring layer, and a source of the transistor is configured to receive the supply voltage from the backside pattern.

According to some aspects, the present disclosure is directed to an integrated circuit including a first front side wiring layer arranged above a front side of a substrate, a backside wiring layer arranged on a backside of the substrate and including a first backside pattern, a first through-via arranged on the first backside pattern and passing through the substrate in a vertical direction, and an e-fuse bit cell including an e-fuse and a transistor arranged on the front side of the substrate, wherein the e-fuse includes a first terminal electrically connected to a bit line, a second terminal electrically connected to the transistor via the first backside pattern and the first through-via, and a link between the first terminal and the second terminal, and the first terminal, the second terminal, and the link are included in the first front side wiring layer.

### BRIEF DESCRIPTION OF THE DRAWINGS

Example implementations will be more clearly understood from the following detailed description, taken in conjunction with the accompanying drawings.

FIG. 1 is a layout of an example of an integrated circuit according to some implementations.

FIG. 2 is a cross-sectional view of the integrated circuit taken along line X1-X1′ of FIG. 1 according to some implementations.

FIG. 3 is a cross-sectional view of the integrated circuit taken along line X1-X1′ of FIG. 1 according to some implementations.

FIG. 4 is a block diagram of an example of a memory device according to some implementations.

FIG. 5 is a circuit diagram of an example of an cell array according to some implementations.

FIGS. 6A and 6B are circuit diagrams showing examples of e-fuse bit cells according to some implementations.

FIG. 7 is a layout of an example of an integrated circuit according to some implementations.

FIG. 8 is a cross-sectional view of the integrated circuit taken along line X2-X2′ of FIG. 7 according to some implementations.

FIG. 9 is a layout of an example of an integrated circuit according to some implementations.

FIG. 10 is a cross-sectional view of the integrated circuit taken along line X3-X3′ of FIG. 9 according to some implementations.

FIG. 11 is a layout of an example of an integrated circuit according to some implementations.

FIG. 12 is a cross-sectional view of the integrated circuit taken along linen X4-X4′ of FIG. 11 according to some implementations.

FIG. 13 is a cross-sectional view of the integrated circuit taken along line X5-X5′ of FIG. 11 according to some implementations.

FIG. 14 is a layout of an example of an integrated circuit according to some implementations.

FIG. 15 is a cross-sectional view of the integrated circuit taken along line X6-X6′ of FIG. 15 according to some implementations.

FIG. 16 is a layout of an example of an integrated circuit according to some implementations.

FIG. 17 is a cross-sectional view of the integrated circuit taken along line X7-X7′ of FIG. 16 according to some implementations.

FIG. 18 is a layout of an example of an integrated circuit according to some implementations.

FIG. 19 is a cross-sectional view of the integrated circuit taken along line X8-X8′ of FIG. 18 according to some implementations.

FIG. 20 is a layout of an example of an integrated circuit according to some implementations.

FIG. 21 is a cross-sectional view of the integrated circuit taken along line X9-X9′ of FIG. 20 according to some implementations.

FIG. 22 is a layout of an example of an integrated circuit according to some implementations.

FIG. 23 is a cross-sectional view of the integrated circuit taken along linen X10-X10′ of FIG. 22 according to some implementations.

FIG. 24 is a cross-sectional view of the integrated circuit taken along line X11-X11′ of FIG. 22 according to some implementations.

FIG. 25 is a layout of an example of an integrated circuit according to some implementations.

FIG. 26 is a cross-sectional view of the integrated circuit taken along line X12-X12′ of FIG. 25 according to some implementations.

FIG. 27 is a layout of an example of an integrated circuit according to some implementations.

FIG. 28 is a cross-sectional view of the integrated circuit taken along line X13-X13′ of FIG. 27 according to some implementations.

FIG. 29 is a layout of an example of an integrated circuit according to some implementations.

FIG. 30 is a cross-sectional view of the integrated circuit taken along line X14-X14′ of FIG. 29 according to some implementations.

FIG. 31 is a layout of an example of an integrated circuit according to some implementations.

FIG. 32 is a cross-sectional view of the integrated circuit taken along line X15-X15′ of FIG. 31 according to some implementations.

FIG. 33 is a layout of an example of an integrated circuit according to some implementations.

FIG. 34 is a cross-sectional view of the integrated circuit taken along line X16-X16′ of FIG. 33 according to some implementations.

FIG. 35 is a layout of an example of an integrated circuit according to some implementations.

FIG. 36 is a cross-sectional view of the integrated circuit taken along line X17-X17′ of FIG. 35 according to some implementations.

FIG. 37 is a layout of an example of an integrated circuit according to some implementations.

FIG. 38 is a cross-sectional view of the integrated circuit taken along line X18-X18′ of FIG. 37 according to some implementations.

FIGS. 39A to 39D are diagrams showing examples of elements according to some implementations.

FIG. 40 is a flowchart illustrating an example of a method of manufacturing an integrated circuit according to some implementations.

FIG. 41 is a block diagram of an example of a system-on-chip according to some implementations.

FIG. 42 is a block diagram of an example of a computing system including a memory for storing a program according to some implementations.

### DETAILED DESCRIPTION

Hereinafter, example implementations will be explained in detail with reference to the accompanying drawings. Like reference numerals denote the same elements on the drawings, and detailed descriptions thereof are omitted.

In the present disclosure, an X direction may be referred to as a first direction, a Y direction may be referred to as a second direction, and a Z direction may be referred to as a vertical direction. The plane consisting of/defined by the X-axis and the Y-axis may be referred to as a horizontal plane. Components arranged in the +Z-axis direction relative to other components may be referred to as being above other components, and components arranged in the −Z-axis direction relative to other components may be referred to as being below other components.

In some implementations, an integrated circuit may be designed by placing a plurality of standard cells. A standard cell is a unit of a layout of an integrated circuit and may be referred to as a “cell” according to an embodiment. A standard cell may be designed to include a plurality of transistors in order to carry out predetermined functions. A standard cell design method refers to a method of designing a dedicated large scale integrated circuit (LSI) to satisfy one or more design constraints resulting from a customer or user's specification, by preparing standard cells with multiple functions and combining certain standard cells. Standard cells may be registered (or stored for later reference) in the computer following design and verification, and logic design resulting from combined standard cells, placement, and routing may be obtained through the use of computer-aided design (CAD) techniques and tools. When designing the integrated circuit, performance of the integrated circuit may be further improved by reducing the lengths of interconnections and/or vias and routing complexity.

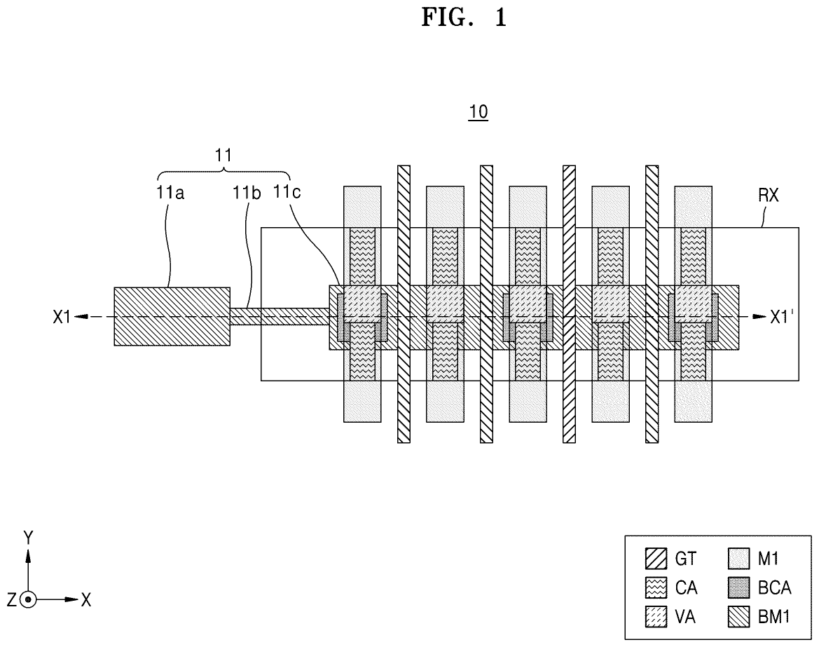

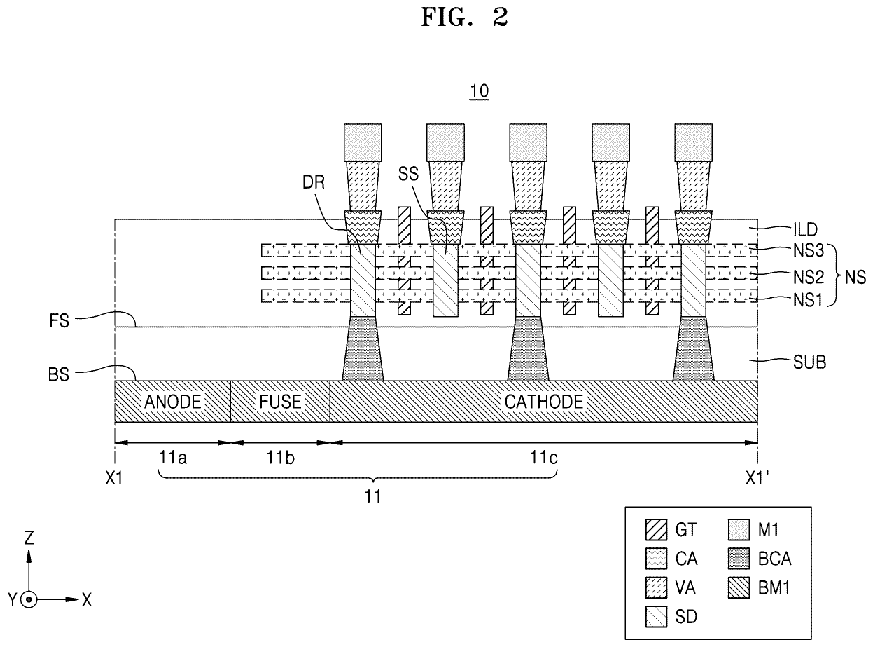

FIG. 1 is a layout of an example of an integrated circuit according to some implementations. FIG. 2 is a cross-sectional view of the integrated circuit taken along line X1-X1′ of FIG. 1 according to some implementations.

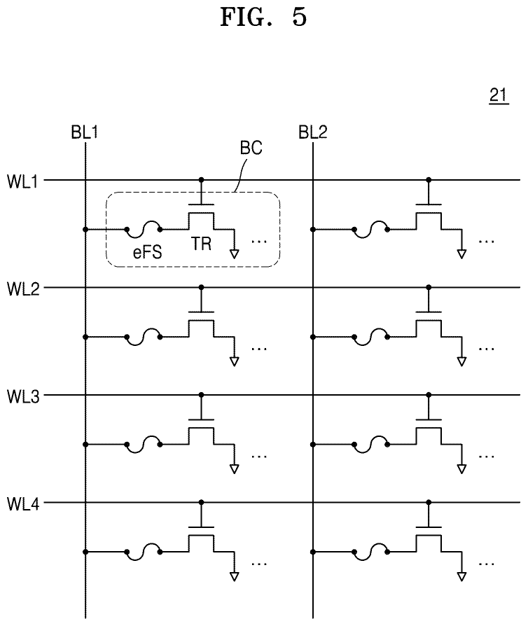

In FIGS. 1 and 2, an integrated circuit 10 may include an active region RX, gate lines GT, contacts CA, first vias VA, a first front side wiring layer M1, a first backside wiring layer BM1, and backside contacts BCA. For example, the integrated circuit 10 of FIG. 1 may correspond to an implementation example of an e-fuse bit cell BC of FIG. 5. For example, an e-fuse eFS included in the e-fuse bit cell BC may be implemented as the first backside wiring layer BM1, and a transistor TR included in the e-fuse bit cell BC may include gate lines GT and source/drain regions SD, and wirings for connecting the e-fuse eFS to the transistor TR may be implemented as backside contacts BCA.

The integrated circuit 10 may be implemented as a semiconductor device, and a substrate SUB on which the semiconductor device is formed may have a first surface FS and a second surface BS. The first surface FS may be a surface, for example, on which circuit elements such as a transistor, are arranged, and the first surface FS may be referred to as a front side. The second surface BS may be opposite to the first surface FS and may be referred to as a backside. The integrated circuit 10 may implement a power distribution network (PDN) by using the first front side wiring layer M1 and the first backside wiring layer BM1. As such, some of signals and/or power applied to the integrated circuit 10 may be transferred through front side wiring layers including the first front side wiring layer M1, that is, front side PDN (FSPDN), and the other may be transferred via backside wiring layers including the first backside wiring layer BM1, that is, backside PDN (BSPDN). Accordingly, the routing complexity may be greatly reduced as compared with a structure in which interconnections are only arranged on the front surface FS of the substrate SUB, and the length of each interconnection or via may be reduced, and the performance of the integrated circuit 10 may be improved.

For example, the substrate SUB may include one of silicon, silicon-on-insulator, silicon-on-sapphire, germanium, silicon-germanium, and gallium-arsenide. An interlayer insulating layer ILD may be arranged on the substrate SUB. The interlayer insulating layer ILD may include an insulating material, for example, the insulating material may include one of oxide layer, nitride layer, and oxynitride layer.

In some implementations, the substrate SUB may correspond to a bulkless substrate. During a process of manufacturing the integrated circuit 10, a device wafer may be formed by forming gate lines, source/drain regions, contacts, vias, and/or wiring layers on the front surface of the substrate SUB. Next, the device wafer is temporarily bonded to a carrier wafer, and a back-grinding process is performed on the device wafer to remove at least a part from the substrate. As described above, a wafer that is back-ground so that the height of the substrate is a reference height or less may be referred to as “bulkless wafer” or “bulkless substrate”.

The active region RX may extend in the first direction X. For example, the active region RX may be defined by an isolation layer such as a shallow trench isolation (STI) or may be referred to as a diffusion region. The diffusion region is a region doped with impurities changing electrical characteristics of a substrate material and may form source/drain regions SD of the transistor. The source/drain regions SD may include an epitaxial area of a semiconductor material such as silicon, boron, tin, germanium, carbon, SiGe, and/or SiC. The contacts CA may each extend in a second direction Y above the active region RX, and the first vias VA may be respectively arranged on the contacts CA. For example, the contacts CA may be respectively on the source/drain regions SD and may be referred to as source/drain contacts.

A nanosheet stack NS extending in the first direction X may be arranged above the front side FS of the substrate SUB. The nanosheet stack NS may include a plurality of nano-sheets overlapping in the vertical direction (Z), for example, first to third nano-sheets NS1 to NS3. For example, the nanosheet stack NS may be doped with N-type impurities and may form an N-type transistor. In another example, the nanosheet stack NS may be doped with P-type impurities and may form a P-type transistor. In some implementations, the nanosheet stack NS may include Si, Ge, or SiGe. In an embodiment, the nanosheet stack NS may include InGaAs, InAs, GaSb, InSb, or a combination thereof.

The gate lines GT may each extend in the second direction Y and may be spaced apart from one another in the first direction X. Each of the gate lines GT may cover the nanosheet stack NS and may surround each of the first to third nano-sheets NS1 to NS3. As such, the first to third nano-sheets NS1 to NS3 may each have a gate all around (GAA) structure. The gate lines GT may be defined as conductive segments including a conductive material such as polysilicon and one or more metals. A gate insulating layer may be disposed between each of the gate lines GT and the first to third nano-sheets NS1 to NS3.

The first front side wiring layer M1 may include a plurality of front side patterns that are electrically connected to the source/drain regions SD via the first vias VA and the contacts CA. For example, the plurality of front side patterns may each extend in the second direction Y and may be spaced apart from one another in the first direction X. The extending direction, width, and/or length of the front side patterns included in the first front side wiring layer M1 may be variously changed according to some implementations.

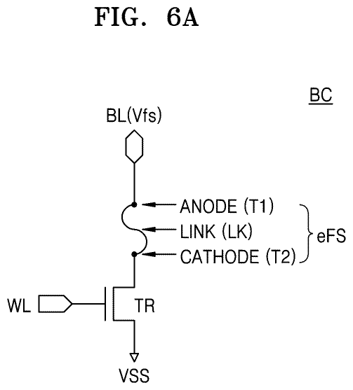

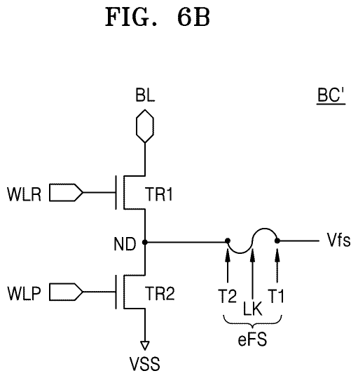

The first backside wiring layer BM1 may include an e-fuse 11, and the e-fuse 11 may include a first terminal 11a, a second terminal 11c, and a fuse link or link 11b between the first and second terminals 11a and 11c. For example, the first terminal 11a, the link 11b, and the second terminal 11c may respectively correspond to an anode T1, a link LK, and a cathode T2 of FIG. 6A, and the first terminal 11a, the link 11b, and the second terminal 11c may form an e-fuse eFS of FIG. 6A.

The second terminal 11c may extend in the first direction X below the source/drain regions SD, and the backside contacts BCA may be arranged on the second terminal 11c. As such, the second terminal 11c may be electrically connected to drain regions DR in the source/drain regions SD via the backside contacts BCA. As described above, the backside contacts BCA may connect layers and elements on the rear surface BS to the elements in the substrate SUB, for example, source/drain regions SD. In detail, the backside contacts BCA may be respectively connected to the drain regions DR in the active region RX. As described above, a structure connecting the contacts to the lower portions of the source/drain regions SD may be referred to as a direct backside contact (DBC). According to some implementations, the DBC may include a backside contact and/or backside via.

The first terminal 11a, the link 11b, and the second terminal 11c may be arranged in the first direction X. For example, the lengths of the first terminal 11a and the second terminal 11c in the second direction Y, that is, widths, may be greater than the length of the link 11b in the second direction Y, that is, the width. However, the present disclosure is not limited thereto, and in some implementations, the first terminal 11a, the link 11b, and the second terminal 11c may be arranged in the second direction Y. Here, the lengths of the first terminal 11a and the second terminal 11c in the first direction X, that is, the widths, may be greater than the length of the link 11b in the first direction X, that is, the width.

As described above, according to some implementations, the e-fuse 11 may be included in the first backside wiring layer BM1 and may be implemented as the BSPDN, and as such, the routing resources for the e-fuse 11 may increase. In detail, the parasitic resistance may be reduced by increasing the width of each of the first terminal 11a, the link 11b, and the second terminal 11c. Also, as the e-fuse 11 is implemented as the BSPDN, the routing resources of the FSPDN including the first front side wiring layer M1 may increase. Accordingly, the size of the integrated circuit 10 including the e-fuse bit cell BC may be decreased, and according to the reduction in the parasitic resistance, the performance of the integrated circuit 10 may increase, and thus, the power performance area (PPA) of the integrated circuit 10 may be improved.

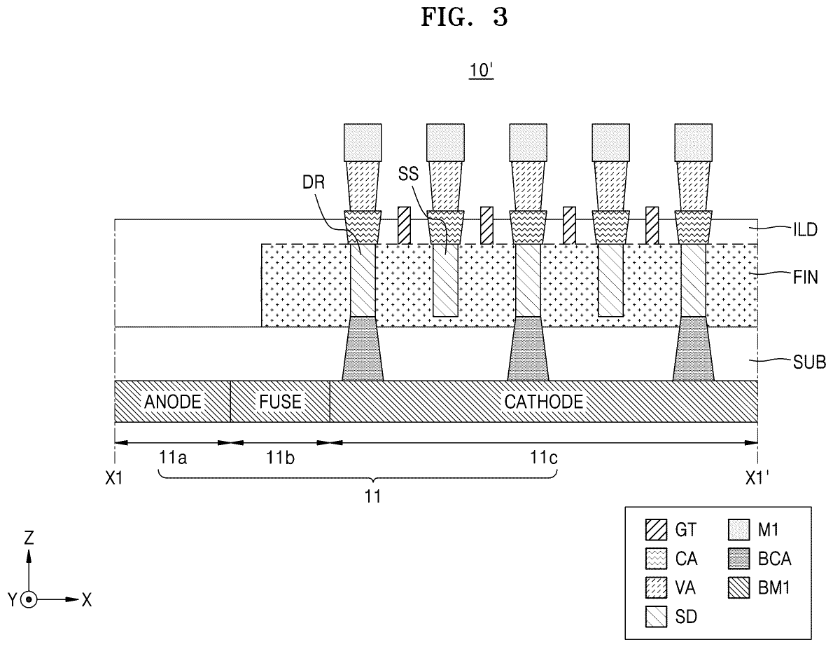

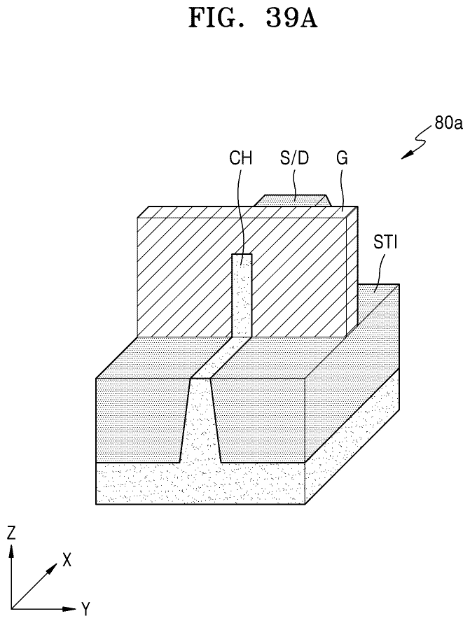

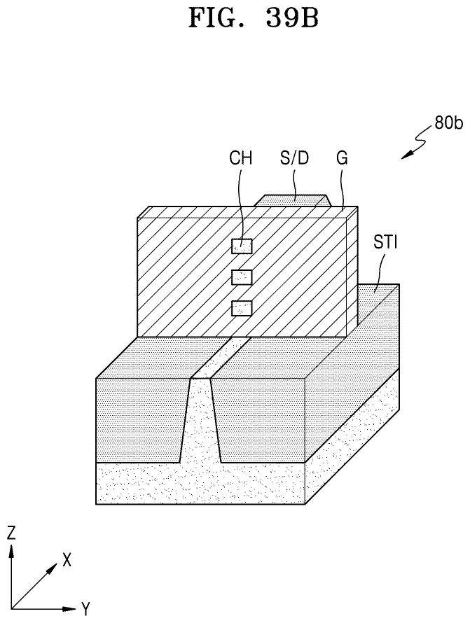

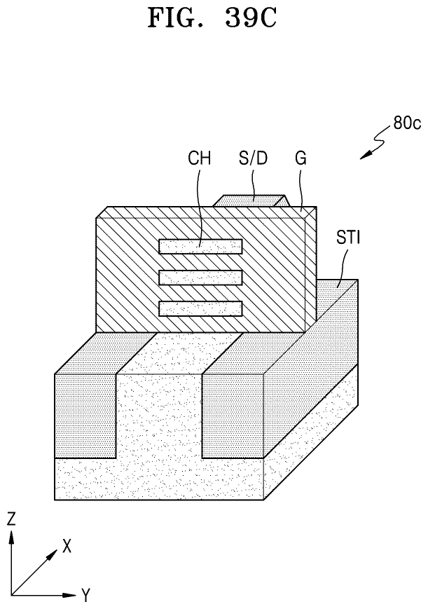

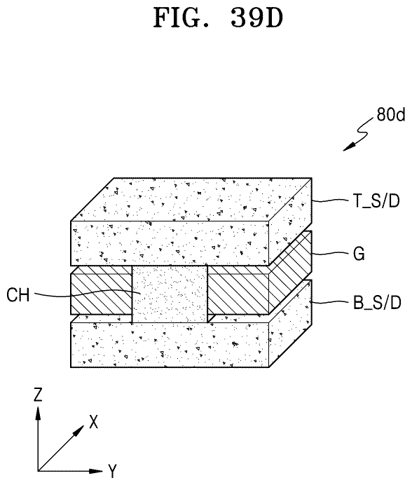

FIG. 3 is a cross-sectional view of the integrated circuit taken along line X1-X1′ of FIG. 1 according to some implementations. In FIG. 3, an integrated circuit 10′ may correspond to a modified example of the integrated circuit 10 shown in FIGS. 1 and 2. The integrated circuit 10′ may include a fin structure FIN, instead of the nanosheet stacks NS, and accordingly, transistors included in the integrated circuit 10′ may be implemented as FinFETs. Hereinafter, the transistor included in the e-fuse bit cell according to some implementations may be shown as an MBCFET including the nanosheet stack, as an example. However, the transistor included in the e-fuse bit cell according to the embodiments may be implemented as the FinFET as shown in FIG. 3. Moreover, the transistor included in the e-fuse bit cell according to some implementations may be employed in various methods, which are described in detail below with reference to FIGS. 39A to 39D.

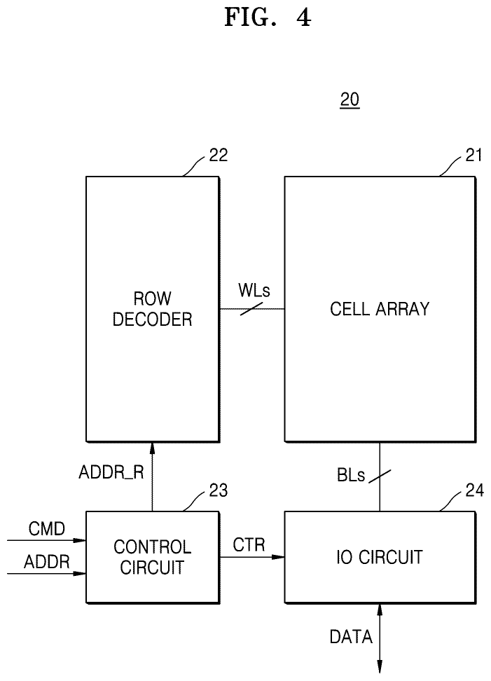

FIG. 4 is a block diagram of an example of a memory device according to some implementations. In FIG. 4, a memory device 20 may include a cell array 21, a row decoder 22, a control circuit 23, and an input/output (I/O) circuit 24. Here, the row decoder 22, the control circuit 23, and the I/O circuit 24 may be collectively referred as peripheral circuits. According to some implementations, the peripheral circuits may further include a command buffer, an address buffer, and/or a voltage generator. For example, the memory device 20 may be implemented as the integrated circuit 10 of FIG. 1.

The memory device 20 may receive a command CMD, an address ADDR, and data DATA. For example, the memory device 20 may receive a command CMD, an address ADDR, and data DATA for instructing a writing operation and may store the data DATA in a region of the cell array 21, which corresponds to the address ADDR. Also, the memory device 20 may receive a command CMD and an address ADDR for instructing a reading operation and may output data stored in the region of the cell array 21, which corresponds to the address ADDR.

The cell array 21 may include a plurality of bit cells or memory cells accessed by a plurality of word lines WLs and a plurality of bit lines BLs. In some implementations, the memory cells included in the cell array 21 may be one-time programmable (OTP) bit cells, for example, e-fuse bit cells. However, the present disclosure is not limited thereto, and in some implementations, the memory cells included in the cell array 21 may be volatile memory cells, such as static random access memory (SRAM), dynamic random access memory (DRAM), etc. In some implementations, the memory cells included in the cell array 21 may be non-volatile memory cells, such as flash memory, resistive random access memory (RRAM), etc. Some implementations are described mainly with reference to the e-fuse bit cells as described below with reference to FIGS. 5 to 6B, but one or more implementations are not limited thereto.

The control circuit 23 may generate a row address ADDR_R and a control signal CTR, based on the command CMD and the address ADDR. The row decoder 22 may be connected to the cell array 21 via the plurality of word lines WLs and may activate one of the plurality of word lines WLs according to the row address ADDR_R. The I/O circuit 24 may be connected to the cell array 21 via the plurality of bit lines BLs and may perform a reading operation or writing operation according to the control signal CTR. For example, the I/O circuit 24 may include a column driver. The column driver may sense a current and/or voltage from the plurality of bit lines BLs or may apply the current and/or voltage to the plurality of bit lines BLs, at the timing determined based on the control signal CTR.

FIG. 5 is a circuit diagram of an example of a cell array according to some implementations. In FIG. 5, the cell array 21 may include the e-fuse bit cells BC connected to word lines WL1 to WL4 or bit lines BL1 and BL2. For example, the e-fuse bit cell BC may be connected to the word line WL1 and the bit line BL1 and may include an e-fuse eFS and a transistor TR. In the present disclosure, the integrated circuits 10, 10′, 10a, 30 to 70d shown in FIGS. 1 to 3 and FIGS. 7 to 38 may correspond to various implementations employing the e-fuse bit cell BC. As described above, implementations examples of the e-fuse bit cell BC are shown in FIGS. 1 to 3 and FIGS. 7 to 37, but the examples may be also applied to other e-fuse bit cells included in the cell array 21.

FIG. 6A is a circuit diagram showing an example of an e-fuse bit cell according to some implementations. In FIG. 6A, a e-fuse bit cell BC may include the e-fuse eFS and the transistor TR. The e-fuse eFS may include an anode T1, a cathode T2, and a link LK between the anode T1 and the cathode T2. The link LK includes a conductive material and, in some implementations, may be referred to as a metal link, a metal stripe, or a fuse link. In the present disclosure, the anode T1 may be referred to as a first terminal and the cathode T2 may be referred to as a second terminal. For example, the width of the link LK may be less than that of the anode T1 and the cathode T2. For example, the length of the link LK may be greater than that of the anode T1 and cathode T2. As described above, the link LK may be employed by a lean and thin metal material, as compared with the anode T1 and the cathode T2. However, the present disclosure is not limited thereto, and the widths and/or lengths of the anode T1, the cathode T2, and/or the link LK may be variously modified according to some implementations.

The anode T1 may be electrically connected to the bit line BL and may receive a fuse source voltage Vfs from the bit line BL. The cathode T2 may be electrically connected to the transistor TR. The e-fuse eFS is an element of which opposite ends are opened or in a high-resistive state when high voltage is applied to the opposite ends thereof and for example, may have a high-resistive value because electromigration occurs due to the high voltage.

The transistor TR may include a gate connected to the word line WL, a drain connected to the cathode T2, and a source receiving a supply voltage, for example, a ground voltage VSS. During a programming operation, a driving voltage is applied to the word line WL and a fuse source voltage Vfs of high voltage may be applied to the bit line BL, and accordingly, the e-fuse eFS may be disconnected. The e-fuse eFS may indicate that the data is programmed with high resistive value.

FIG. 6B is a circuit diagram showing an example of an e-fuse bit cell according to some implementations. In FIG. 6B, an e-fuse bit cell BC′ may include the e-fuse eFS, a programming transistor TR2, and a read transistor TR1. The programming transistor TR2 may include a gate connected to a programming word line WLP, a drain connected to a node ND, and a source to which a supply voltage, e.g., a ground voltage VSS, is applied. The read transistor TR1 may include a gate connected to a read word line WLR, a drain connected to the node ND, and a source connected to the bit line BL. The e-fuse eFS may include the anode T1 receiving the fuse source voltage Vfs, the cathode T2 connected to the node ND, and the link LK between the anode T1 and the cathode T2.

During the programming operation, the driving voltage is applied to the program word line WLP, the fuse source voltage Vfs of high voltage may be applied to the anode T1 of the e-fuse eFS, and accordingly, the e-fuse eFS may be disconnected. The e-fuse eFS may indicate that the data is programmed with high resistive value. During the reading operation, the read word line WLR is applied with a read voltage, and the ground voltage VSS may be applied to the anode T1 of the e-fuse eFS. Accordingly, a current path through the bit line BL, the read transistor TR1, and the e-fuse eFS may be formed. Here, according to whether the e-fuse eFS that is programmed is disconnected, the voltage level of the bit line BL is differently output, and thus, the data may be read.

As an element is developed through an end-of-line process, the size of the e-fuse bit cell BC or BC′ may decrease. According to the reduction in the size of the e-fuse bit cell BC or BC′, routing resources connected to the e-fuse bit cell BC may be reduced, and due to the increase in the parasitic resistance caused therefrom, the performance of the memory device may degrade. Accordingly, in order to sufficiently perform a programming operation or reading operation on the e-fuse bit cell BC or BC′, it is important to decrease the parasitic resistance of the e-fuse bit cell BC or BC′ when designing the layout of the IC including the e-fuse bit cell BC or BC′.

According to some implementations, various layouts and designing methods capable of reducing the parasitic resistance of the e-fuse bit cell BC are suggested by increasing the widths and the number of interconnections connecting the e-fuse eFS to the transistor TR included in the e-fuse bit cell BC. Also, according to some implementations, various layouts and designing methods capable of reducing the parasitic resistance of the e-fuse bit cell BC by increasing the widths and the number of wirings configured to apply a supply voltage, e.g., a ground voltage VSS, to the transistor TR included in the e-fuse bit cell BC, are provided. According to some implementations, the routing resources connected to the e-fuse bit cell BC may be increased by using BSPDN, and accordingly, the performance of the memory device may be improved due to the reduction in the parasitic capacitance.

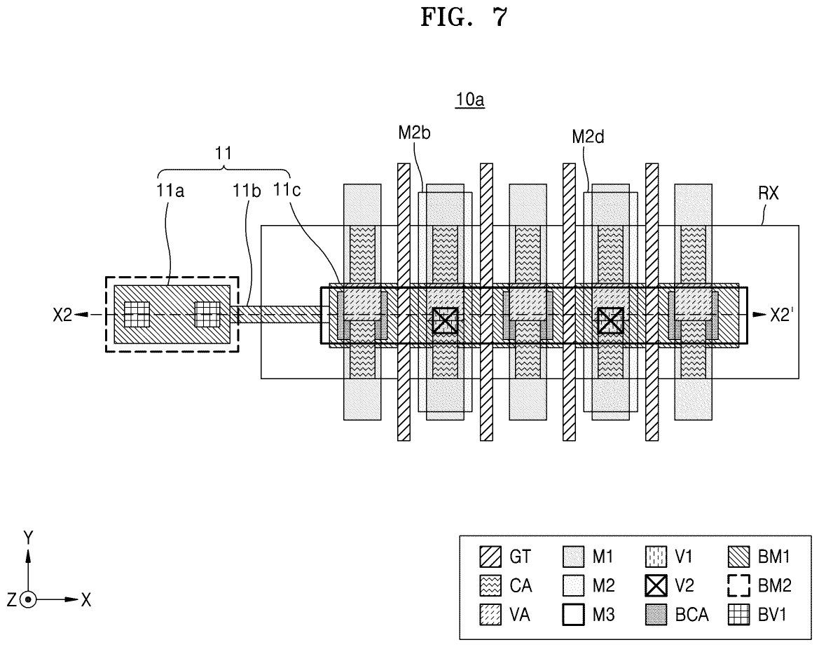

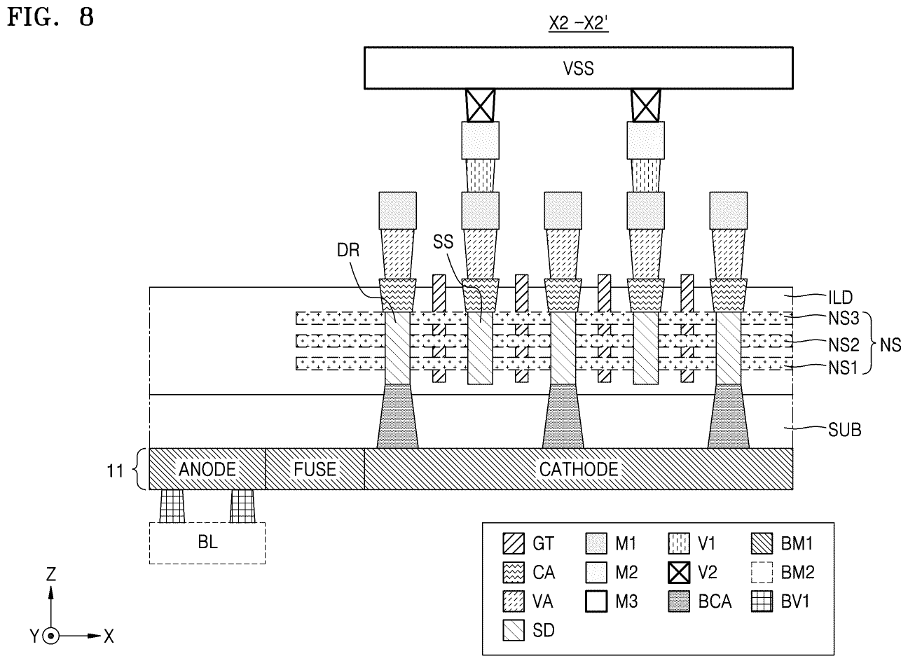

FIG. 7 is a layout of an example of an integrated circuit according to some implementations. FIG. 8 is a cross-sectional view of the integrated circuit taken along line X2-X2′ of FIG. 7 according to some implementations.

In FIGS. 7 and 8, an integrated circuit 10a corresponds to a modified example of the integrated circuit 10 shown in FIG. 1, and descriptions provided above with reference to FIGS. 1 to 6B may be also applied to some implementations. The integrated circuit 10a may further include a second front side wiring layer M2, a third front side wiring layer M3, second and third vias V1 and V2, a first backside via BV1, and a second backside wiring layer BM2, as compared with the integrated circuit 10 of FIG. 1.

The second backside wiring layer BM2 may be arranged below the first backside wiring layer BM1 and may receive a bit line BL signal. The first backside via BV1 may be arranged on the second backside wiring layer BM2 and may electrically connect the first and second backside wiring layers BM1 and BM2 to each other. The first terminal 11a included in the first backside wiring layer BM1 may be electrically connected to the bit line BL via the first backside via BV1 and the second backside wiring layer BM2 and may receive the bit line BL signal.

The second front side wiring layer M2 may be arranged above the first front side wiring layer M1 and may be electrically connected to the first front side wiring layer M1 via the second vias V1. For example, the second front side wiring layer M2 may include wiring patterns that respectively extend in the second direction Y and are spaced apart from one another in the first direction X. The third front side wiring layer M3 may be arranged above the second front side wiring layer M2 and may be electrically connected to the second front side wiring layer M2 via the third vias V2. For example, the third front side wiring layer M3 may extend in the first direction X. The third front side wiring layer M3 may receive the supply voltage, e.g., the ground voltage VSS.

A source region SS of the transistor may receive the ground voltage VSS from an FSPDN including the first to third front side wiring layers M1, M2, and M3. For example, the source region SS may receive the ground voltage VSS via the contact CA, the first via VA, the first front side wiring layer M1, the second via V1, the second front side wiring layer M2, the third via V2, and the third front side wiring layer M3. The wirings for connecting the e-fuse 11 and the drain region DR of the transistor may be implemented as BSPDN. For example, the drain region DR of the transistor may be electrically connected to the second terminal 11c via the backside contacts BCA.

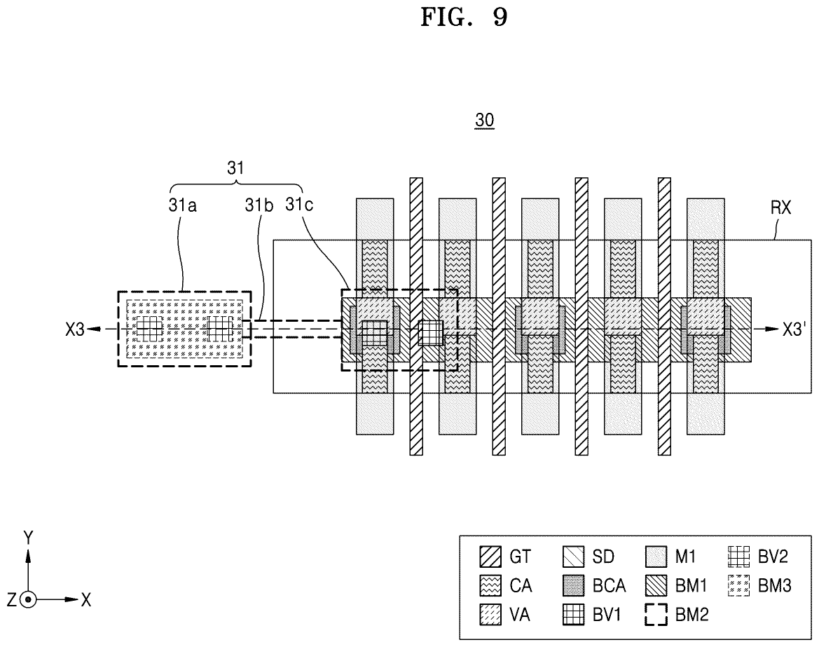

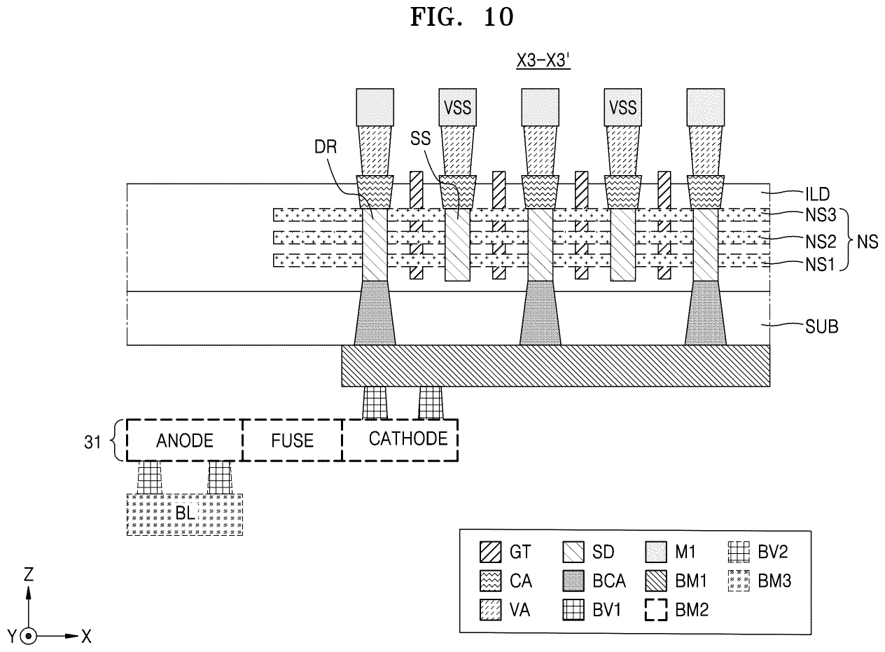

FIG. 9 is a diagram showing a layout of an example of an integrated circuit according to some implementations. FIG. 10 is a cross-sectional view of the integrated circuit taken along line X3-X3′ of FIG. 9 according to some implementations.

In FIGS. 9 and 10, an integrated circuit 30 may include the active region RX, the gate lines GT, the contacts CA, the first vias VA, the first front side wiring layer M1, the first to third backside wiring layers BM1, BM2, and BM3, the backside contacts BCA, and first and second backside vias BV1 and BV2. The integrated circuit 30 corresponds to the modified example of the integrated circuit 10 shown in FIG. 1, and unlike that the e-fuse 11 of FIG. 1 is implemented as the first backside wiring layer BM1, an e-fuse 31 may be employed as the second backside wiring layer BM2 according to some implementations.

The second backside wiring layer BM2 may include the e-fuse 31, and the e-fuse 31 may include a first terminal 31a, a second terminal 31c, and a link 31b between the first and second terminals 31a and 31c. The first terminal 31a may be electrically connected to the bit line BL via the second backside via BV2 and the third backside wiring layer BM3 and may receive a bit line BL signal. The second terminal 31c may be electrically connected to the drain region DR of the transistor via the first backside via BV1, the first backside wiring layer BM1, and the backside contacts BCA. The source region SS of the transistor may receive the supply voltage, e.g., the ground voltage VSS, via the FSPDN including the first and second front side wiring layers M1 and M2.

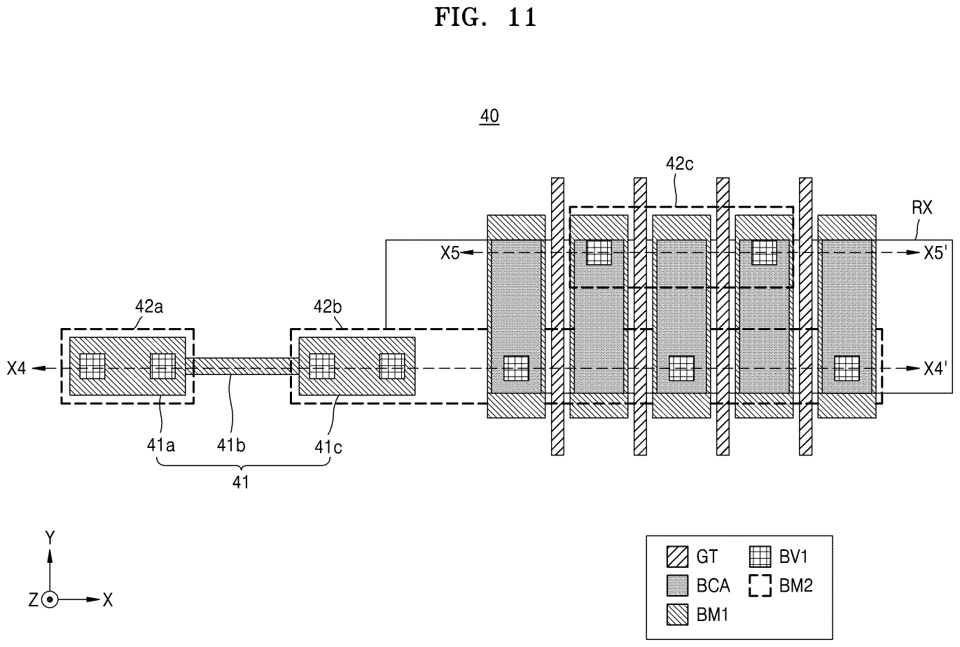

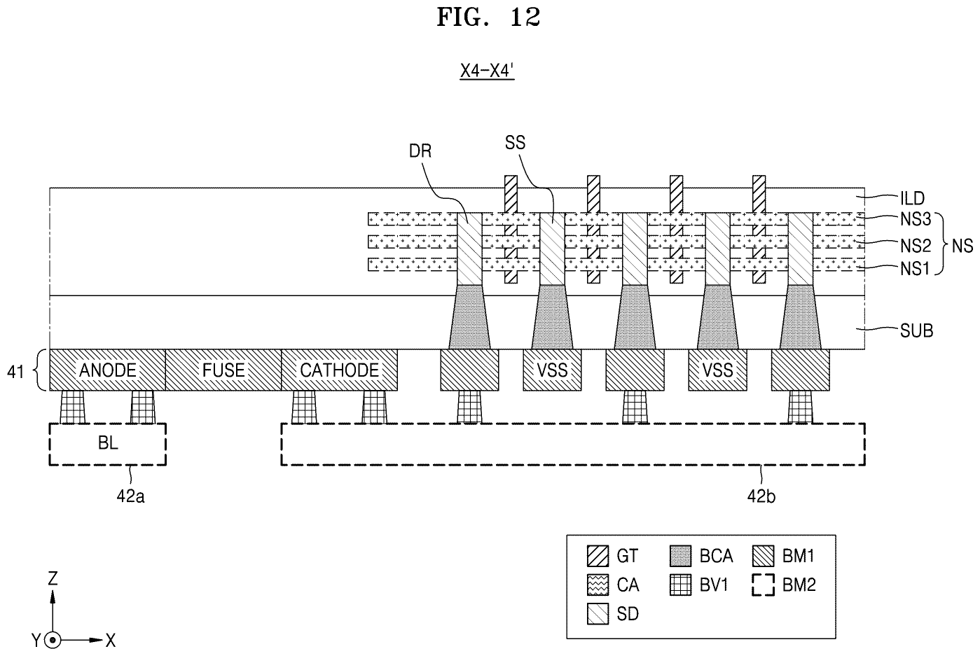

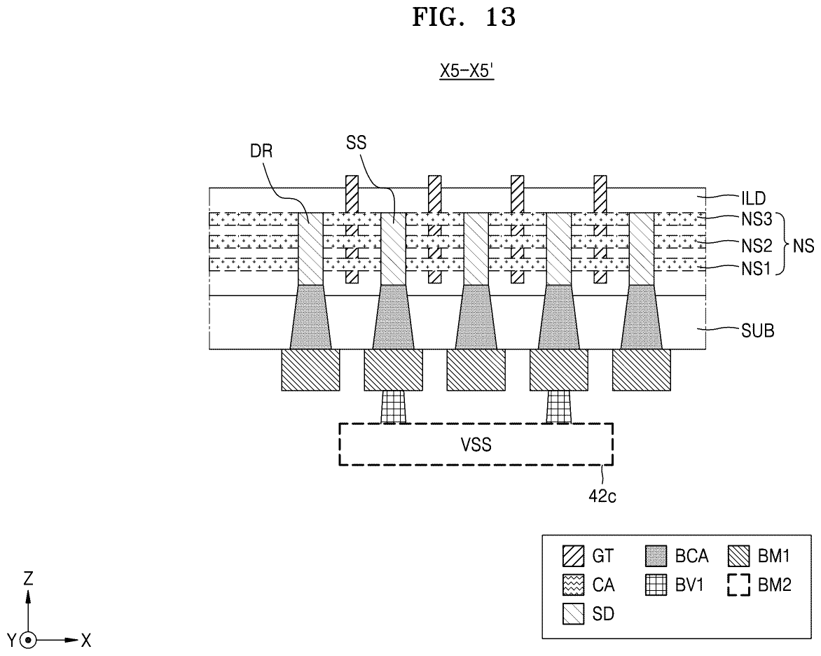

FIG. 11 is a layout of an example of an integrated circuit according to some implementations. FIG. 12 is a cross-sectional view of the integrated circuit taken along linen X4-X4′of FIG. 11 according to some implementations. FIG. 13 is a cross-sectional view of the integrated circuit taken along line X5-X5′ of FIG. 11 according to some implementations.

In FIGS. 11 to 13, an integrated circuit 40 may include the active region RX, the gate lines GT, the backside contacts BCA, the first and second backside wiring layers BM1 and BM2, and the first backside vias BV1. The first backside wiring layer BM1 may include a plurality of backside patterns that each extend in the second direction Y and are spaced apart from one another in the first direction X. The second backside wiring layer BM2 may be arranged below the first backside wiring layer BM1 and may include backside patterns 42a, 42b, and 42c. For example, the backside pattern 42a may receive a bit line BL signal, the backside pattern 42b may be used as a wiring between an e-fuse 41 and the transistor, and the backside pattern 42c may receive the ground voltage VSS.

According to some implementations, the e-fuse 41 may receive the bit line BL signal via the BSPDN. For example, the e-fuse 41 may be implemented as the first backside wiring layer BM1. The e-fuse 41 may include a first terminal 41a, a second terminal 41c, and a link 41b between the first and second terminals 41a and 41c. The first terminal 41a may be electrically connected to the bit line BL via the first backside vias BV1 and the backside pattern 42a included in the second backside wiring layer BM2 and may receive the bit line BL signal.

According to some implementations, the e-fuse bit cell may electrically connect the e-fuse 41 to the drain region DR of the transistor via the BSPDN. For example, the second terminal 41c may be electrically connected to the drain region DR via the first backside vias BV1, the backside pattern 42b included in the second backside wiring layer BM2, the first backside wiring layer BM1, and the backside contacts BCA. According to some implementations, the e-fuse 41 may receive the ground voltage VSS via the BSPDN. For example, the source region SS may receive the ground voltage VSS via the backside contacts BCA, the first backside wiring layer BM1, the first backside vias BV1, and the backside pattern 42c included in the second backside wiring layer BM2.

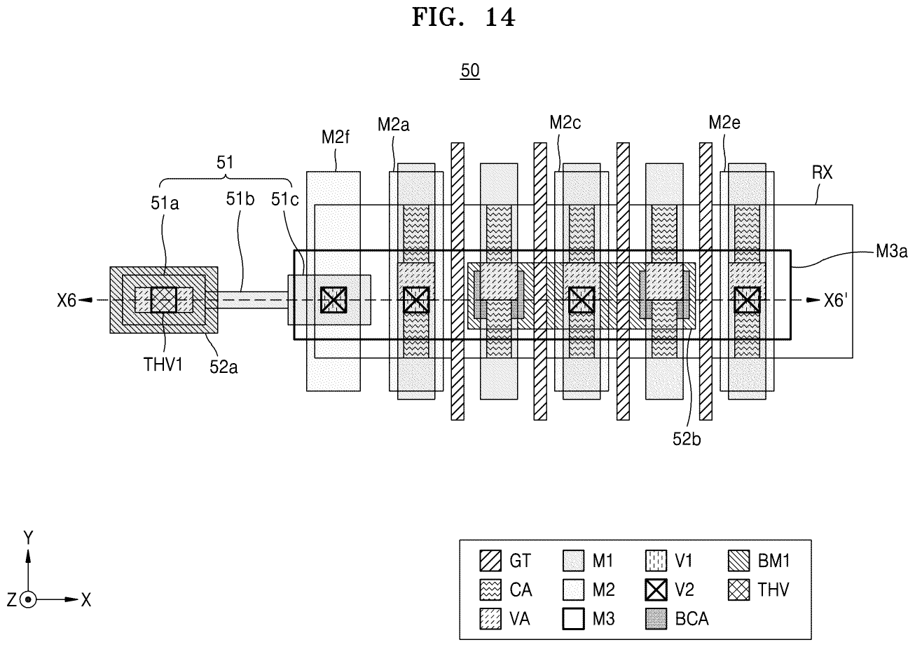

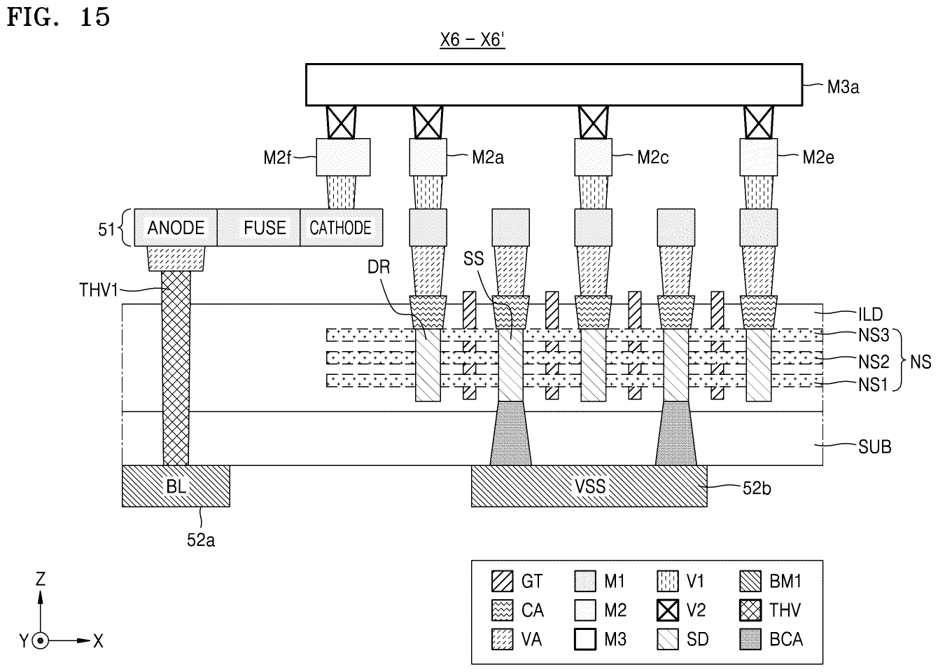

FIG. 14 is a diagram showing a layout of an example of an integrated circuit according to some implementations. FIG. 15 is a cross-sectional view of the integrated circuit taken along line X6-X6′ of FIG. 15 according to some implementations.

In FIGS. 14 and 15, an integrated circuit 50 may include the active regions RX, the gate lines GT, the contacts CA, the first to third vias VA, V1, and V2, the first to third front side wiring layers M1, M2, and M3, a through-hole-via or through-via THV, the backside contacts BCA, and the first backside wiring layer BM1. The through-via THV may include a through-via THV1. According to some implementations, an e-fuse 51 may be arranged in the first front side wiring layer M1. The e-fuse 51 may include a first terminal 51a, a second terminal 51c, and a link 51b between the first and second terminals 51a and 51c.

The first backside wiring layer BM1 may include backside patterns 52a and 52b. For example, the backside pattern 52a may receive the bit line BL signal, and the backside pattern 52b may receive the ground voltage VSS. The second front side wiring layer M2 may include wiring patterns M2a, M2c, M2e, and M2f that each extend in the second direction Y and are spaced apart from one another in the first direction X. For example, the width of the wiring pattern M2f in the first direction X may be greater than the width of each of the wiring patterns M2a, M2c, and M2e in the first direction X, but is not limited thereto. The third front side wiring layer M3 may include a wiring line M3a extending in the first direction X.

According to some implementations, the e-fuse 51 may receive the bit line BL signal via the BSPDN. For example, the through-via THV1 may be arranged on the backside pattern 52a and may pass through the substrate SUB in the vertical direction Z. The first terminal 51a may be electrically connected to the backside pattern 52a via the first via VA and the through-via THV1. As such, the first terminal 51a may be electrically connected to the bit line BL via the first via VA, the through-via THV1, and the backside pattern 52a and may receive the bit line BL signal. For example, the first via VA arranged under the first terminal 51a may have greater width in the first direction X than those of the other first vias VA, but the present disclosure is not limited thereto.

For example, during a programming operation on the e-fuse bit cell, a fuse source voltage Vfs having a high voltage level may be applied to the e-fuse 51 via the bit line BL. According to some implementations, the fuse source voltage Vfs having a high voltage level may be applied to the backside pattern 52a via the BSPDN. Here, because a distance between the backside pattern 52a and the other interconnections, e.g., the first to third front side wiring layers M1, M2, and M3, is relatively large, the parasitic capacitance between the backside pattern 52a and the other wirings may be reduced. Accordingly, during the programming operation on the e-fuse bit cell, the performance of the integrated circuit 50 may be improved.

According to some implementations, the integrated circuit 50 may electrically connect the e-fuse 51 to the drain region DR of the transistor via the FSPDN. For example, the wiring line M3a included in the third front side wiring layer M3 may be used as an interconnection for connecting between the e-fuse 51 and the drain region DR of the transistor. The second terminal 51c may be electrically connected to the drain region DR of the transistor via the FSPDN including the first to third vias VA, V1, and V2, the first to third front side wiring layers M1, M2, and M3, and the contacts CA.

According to some implementations, the source region SS of the transistor may receive the ground voltage VSS via the BSPDN. The backside pattern 52b may be arranged below the source/drain regions SD and may extend, for example, in the first direction X. The backside contacts BCA may be arranged on the backside pattern 52b and may pass through the substrate SUB in the vertical direction Z. The source region SS of the transistor may be electrically connected to the backside pattern 52b via the backside contact BCA and as such, may receive the ground voltage VSS via the backside contact BCA and the backside pattern 52b.

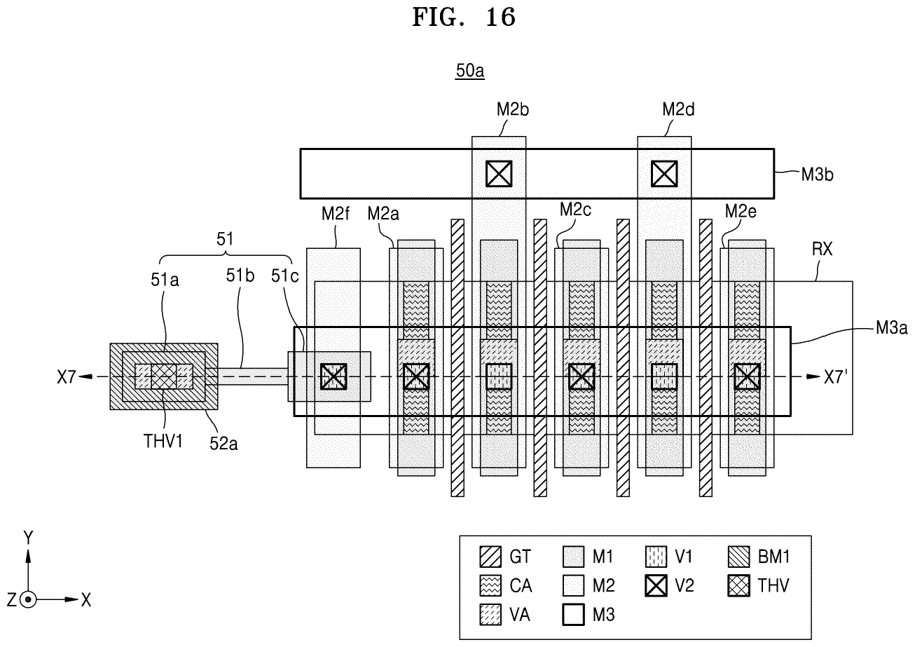

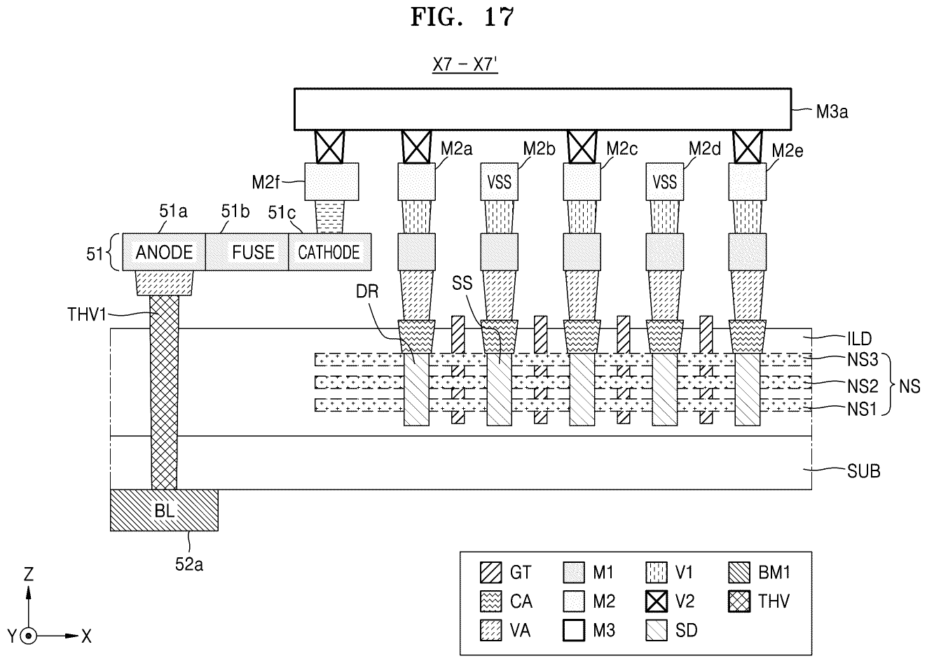

FIG. 16 is a diagram showing a layout of an example of an integrated circuit according to some implementations. FIG. 17 is a cross-sectional view of the integrated circuit taken along line X7-X7′ of FIG. 16 according to some implementations.

In FIGS. 16 and 17, an integrated circuit 50a may correspond to a modified example of the integrated circuit 50 shown in FIGS. 14 and 15. The third front side wiring layer M3 may include wiring lines M3a and M3b. For example, the wiring lines M3a and M3b may respectively extend in the first direction X and may be spaced apart from each other in the second direction Y. The second front side wiring layer M2 may include wiring patterns M2a to M2f. The wiring patterns M2a, M2c, and M2e may be electrically connected to the wiring line M3a via the third vias V2.

According to some implementations, the e-fuse 51 may receive the bit line BL signal via the BSPDN, and the integrated circuit 50a may electrically connect the e-fuse 51 to the drain region DR of the transistor via the FSPDN. According to some implementations, the source region SS of the transistor may receive the ground voltage VSS via the FSPDN. For example, the wiring line M3b included in the third front side wiring layer M3 may receive the ground voltage VSS and may correspond to a power rail supplying the supply voltage to the source region SS. The wiring patterns M2a, M2c, and M2e may be electrically connected to the wiring line M3a via the third vias V2. The wiring pattern M2f may be electrically connected to the second terminal 51c via the second via V1. The wiring patterns M2b and M2d may be electrically connected to the wiring line M3b via the third vias V2 and may receive the ground voltage VSS from the third vias V2 and the wiring line M3b.

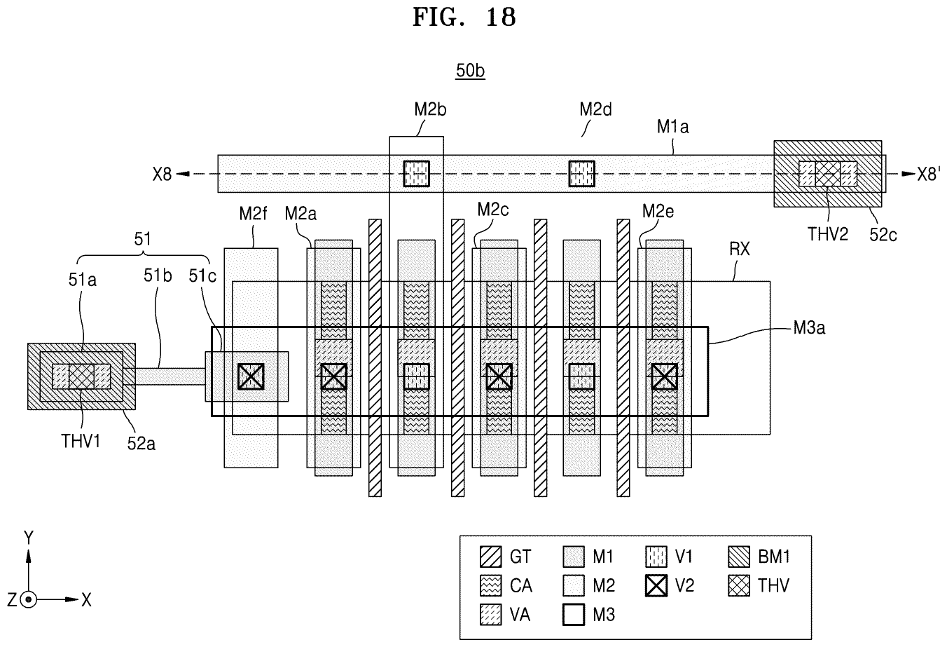

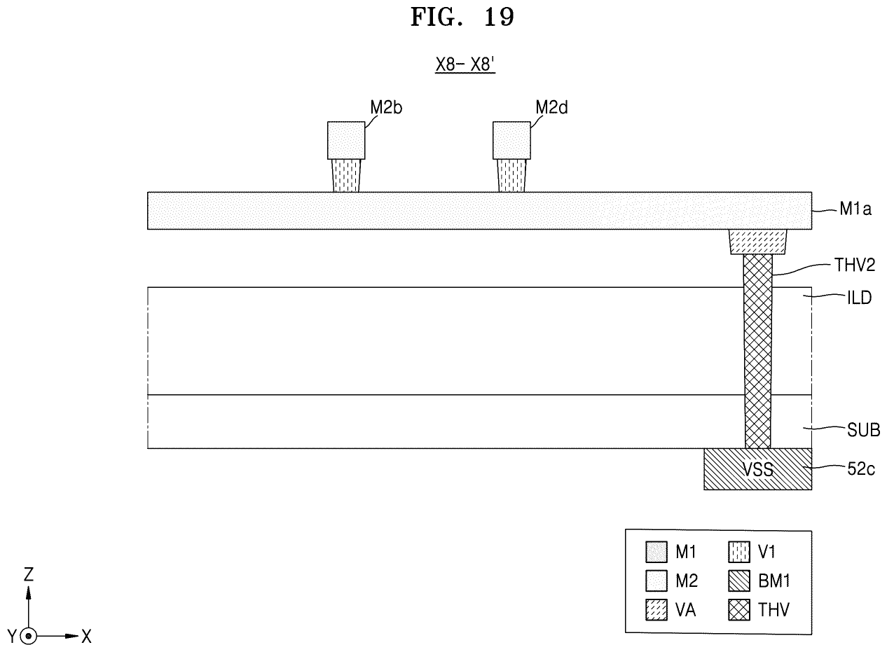

FIG. 18 is a diagram showing a layout of an example of an integrated circuit according to some implementations. FIG. 19 is a cross-sectional view of the integrated circuit taken along line X8-X8′ of FIG. 18 according to some implementations.

In FIGS. 18 and 19, an integrated circuit 50b may correspond to a modified example of the integrated circuit 50a shown in FIGS. 16 and 17. The through-via THV may include through-vias THV1 and THV2. The first front side wiring layer M1 may include the front side pattern M1a extending in the first direction X. The first backside wiring layer BM1 may include backside patterns 52a and 52c.

According to some implementations, the e-fuse 51 may receive the bit line BL signal via the BSPDN, and the integrated circuit 50b may electrically connect the e-fuse 51 to the drain region DR of the transistor via the FSPDN. According to some implementations, the source region SS of the transistor may receive the ground voltage VSS via the FSPDN and the BSPDN. The front side pattern M1a may be electrically connected to the backside pattern 52c via the first via VA and the through-via THV2. Also, the front side pattern M1a may be connected to the wiring patterns M2b and M2d included in the second front side wiring layer M2 via the second via V1. As such, the source region SS may receive the ground voltage VS via the backside pattern 52c, the through-via THV2, the first via VA, the front side pattern M1a, the second via V1, the wiring patterns M2b and M2d, the first via VA, and the contact CA.

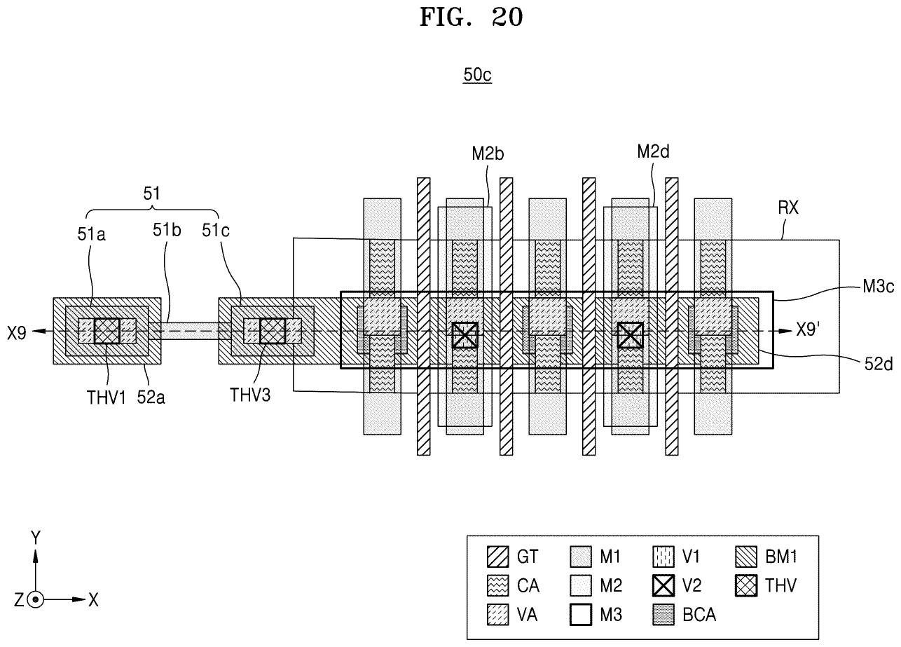

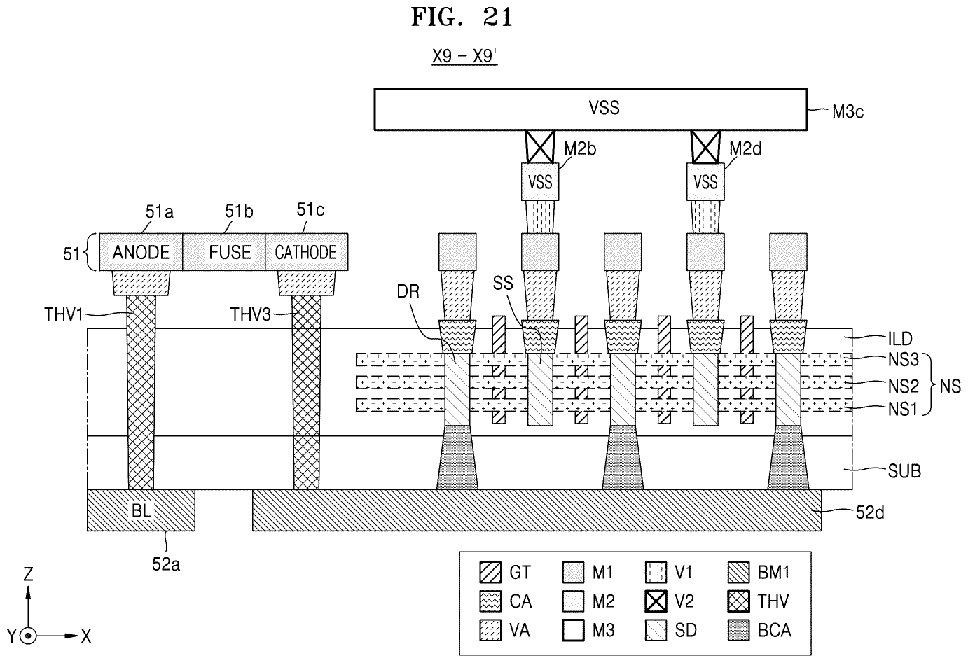

FIG. 20 is a diagram showing a layout of an example of an integrated circuit according to some implementations. FIG. 21 is a cross-sectional view of the integrated circuit taken along line X9-X9′ of FIG. 20 according to some implementations.

In FIGS. 20 and 21, an integrated circuit 50c may correspond to a modified example of the integrated circuit 50 shown in FIGS. 14 and 15. The through via THV may include the through-vias THV1 and THV3. The first backside wiring layer BM1 may include backside patterns 52a and 52d. The second front side wiring layer M2 may include wiring patterns M2b and M2d, and the third front side wiring layer M3 may include the wiring line M3c.

According to some implementations, the e-fuse 51 may receive the bit line BL signal via the BSPDN. According to some implementations, the integrated circuit 50c may electrically connect the e-fuse 51 to the drain region DR of the transistor via the BSPDN. For example, the backside pattern 52d may be used as an interconnection for connecting the e-fuse to the drain region DR of the transistor. The second terminal 51c of the e-fuse 51 may be electrically connected to the backside pattern 52d via the first via VA and the through-via THV3. The backside pattern 52d may be electrically connected to the drain region DR via the backside contacts BCA.

According to some implementations, the source region SS of the transistor may receive the ground voltage VSS via the FSPDN. For example, the wiring line M3c included in the third front side wiring layer M3 may extend in the first direction X and may be arranged above the source/drain regions SD. The wiring patterns M2b and M2d included in the second front side wiring layer M2 may respectively extend in the second direction Y and may be spaced apart from each other in the first direction X. The source region SS may receive the ground voltage VSS via the contact CA, the first to third vias VA, V1, and V2, the first front side wiring layer M1, the wiring patterns M2b and M2d, and the wiring line M3c.

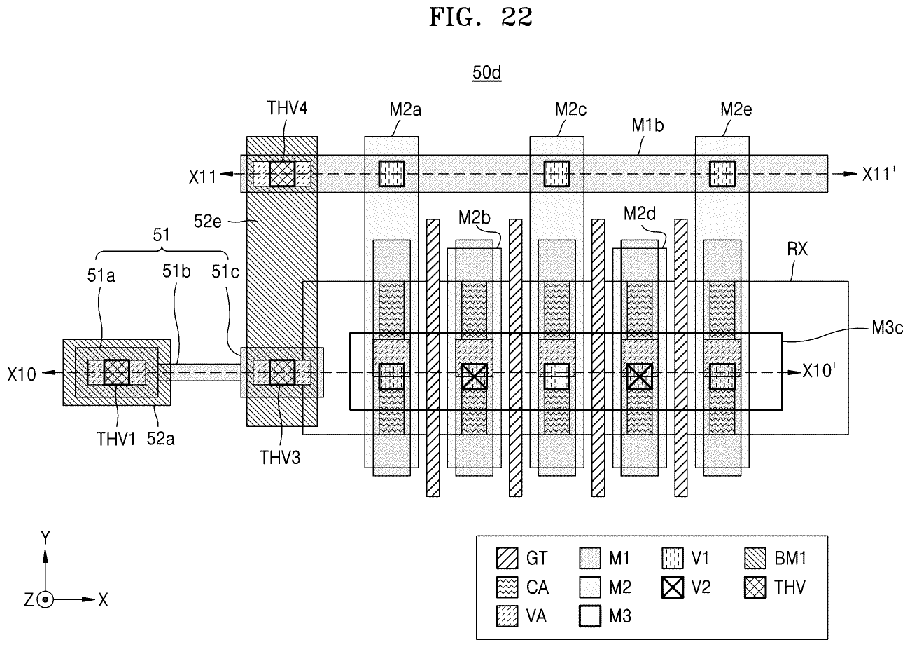

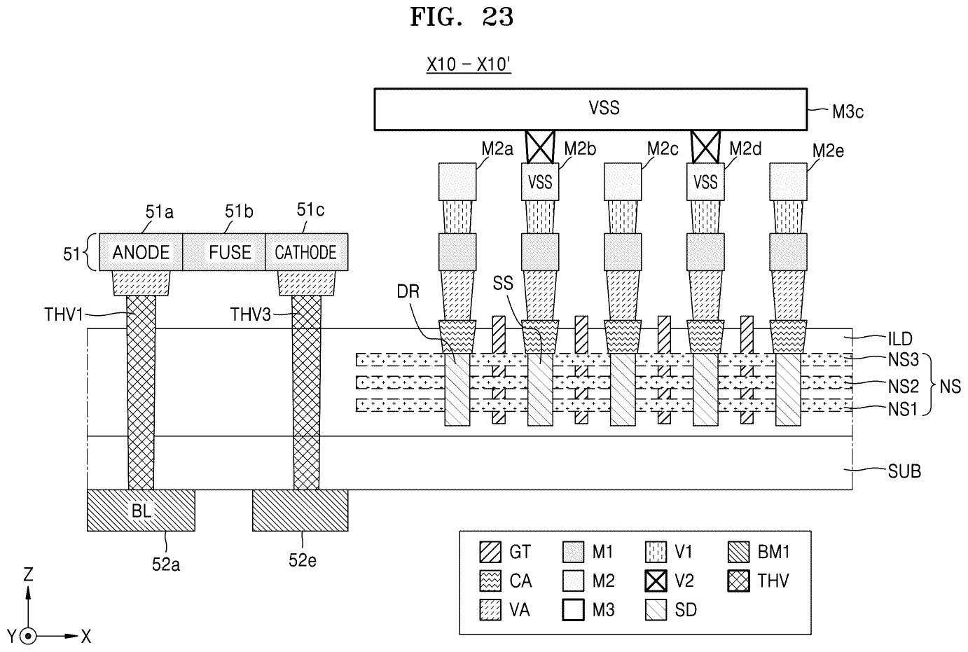

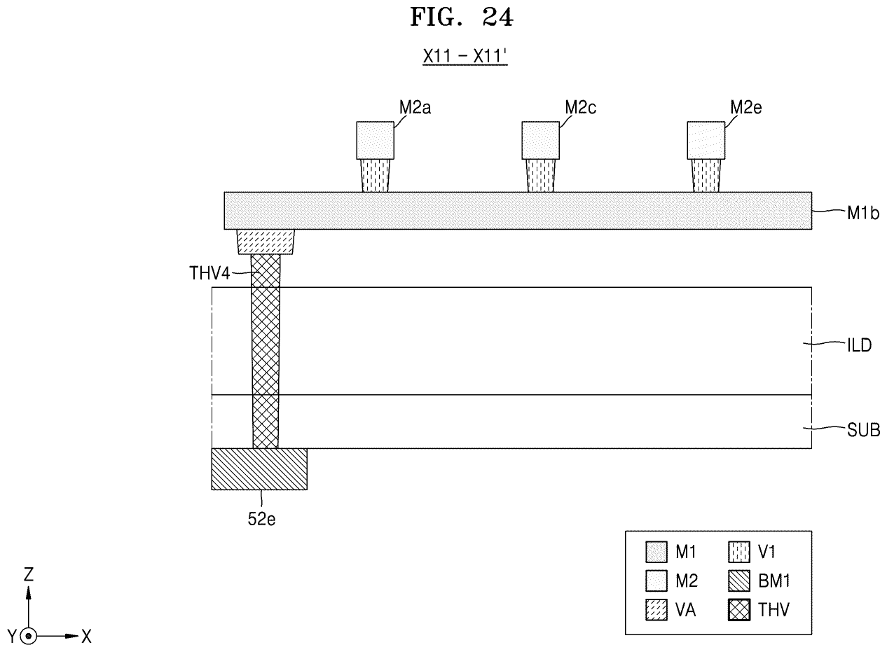

FIG. 22 is a diagram showing a layout of an example of an integrated circuit according to some implementations. FIG. 23 is a cross-sectional view of the integrated circuit taken along linen X10-X10′ of FIG. 22 according to some implementations, and FIG. 24 is a cross-sectional view of the integrated circuit taken along line X11-X11F of FIG. 22 according to some implementations.

In FIGS. 22 to 24, an integrated circuit 50d may correspond to a modified example of the integrated circuit 50a shown in FIGS. 16 and 17. The through via THV may include through-vias THV1, THV3, and THV4. The first backside wiring layer BM1 may include backside patterns 52a and 52e, and the first front side wiring layer M1 may include a front side pattern M1b. The second front side wiring layer M2 may include wiring patterns M2a to M2e extending in the second direction Y, and the third front side wiring layer M3 may include a wiring line M3c.

According to some implementations, the e-fuse 51 may receive the bit line BL signal via the BSPDN. According to some implementations, the integrated circuit 50d may electrically connect the e-fuse 51 to the drain region DR of the transistor via the BSPDN and FSPDN. For example, the second terminal 51c of the e-fuse 51 may be electrically connected to the backside pattern 52e via the first via VA and the through-via THV3. The backside pattern 52e is electrically connected to the front side pattern M1b via the through-via THV4 and the first via VA, and the front side pattern M1b may be connected to the wiring patterns M2a, M2c, and M2e via the second vias V1. As such, the drain region DR may be electrically connected to the second terminal 51c via the through-vias THV3 and THV4 and the wiring patterns M2a, M2c, and M2e.

According to some implementations, the source region SS of the transistor may receive the ground voltage VSS via the FSPDN. For example, the wiring line M3c included in the third front side wiring layer M3 may extend in the first direction X and may be arranged above the source/drain regions SD. The wiring patterns M2b and M2d included in the second front side wiring layer M2 may respectively extend in the second direction Y and may be spaced apart from each other in the first direction X. The source region SS may receive the ground voltage VSS via the contact CA, the first to third vias VA, V1, and V2, the first front side wiring layer M1, the wiring patterns M2b and M2d, and the wiring line M3c.

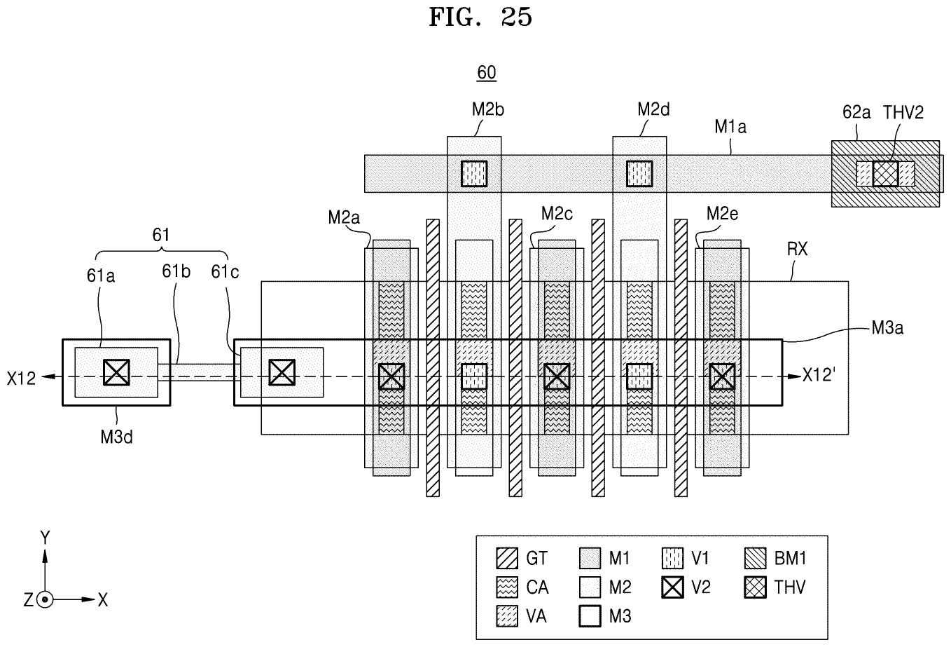

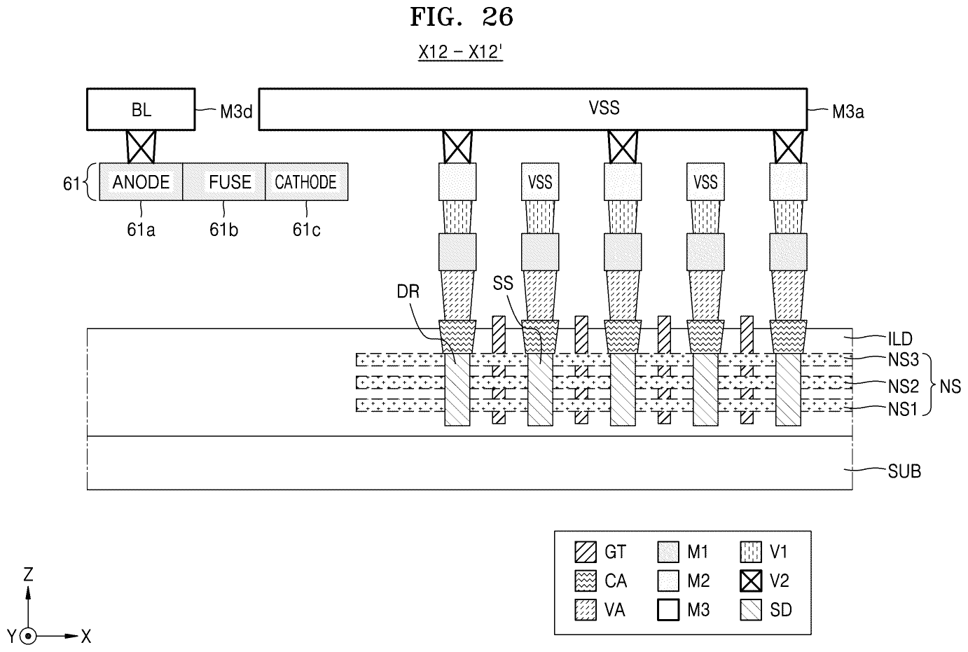

FIG. 25 is a diagram showing a layout of an example of an integrated circuit according to some implementations. FIG. 26 is a cross-sectional view of the integrated circuit taken along line X12-X12′ of FIG. 25 according to some implementations.

In FIGS. 25 and 26, an integrated circuit 60 may include the active region RX, the gate lines GT, the contacts CA, the first to third vias VA, V1, and V2, and the first to third front side wiring layers M1, M2, and M3, the first backside wiring layer BM1, and the through-via THV. The through-via THV may include the through-via THV2, and the first backside wiring layer BM1 may include a backside pattern 62a. An e-fuse 61 may include a first terminal 61a, a link 61b, and a second terminal 61c and may be arranged in the second front side wiring layer M2. The first front side wiring layer M1 may include a front side pattern M1a extending in the first direction X, the second front side wiring layer M2 may further include wiring patterns M2a to M2e, and the third front side wiring layer M3 may include wiring lines M3a and M3d.

In some implementations, the e-fuse 61 may receive the bit line BL signal via the FSPDN. For example, the first terminal 61a may be connected to the wiring line M3d via the third via V2, and the wiring line M3d may be connected to the bit line BL to receive the bit line BL signal. As such, the first terminal 61a may be connected to the bit line BL via the third via V2 and the wiring line M3d and may receive the bit line BL signal.

In some implementations, the integrated circuit 60 may electrically connect the e-fuse 61 to the drain region DR of the transistor via the FSPDN. For example, the wiring line M3a included in the third front side wiring layer M3 may be used as an interconnection for connecting the e-fuse 61 to the drain region DR. The second terminal 61c may be connected to the wiring line M3a via the third via V2, and the wiring line M3a may be connected to the wiring patterns M2a, M2c, and M2e via the second vias V2. As such, the drain region DR may be electrically connected to the second terminal 61c via the contact CA, the first via VA, the first front side wiring layer M1, the second via V1, the wiring patterns M2a, M2c, and M2e, the third via V2, and the wiring line M3a.

According to some implementations, the source region SS of the transistor may receive the ground voltage VSS via the BSPDN. The backside pattern 62a included in the first backside wiring layer BM1 may receive the ground voltage VSS. The through-via THV2 may be arranged on the backside pattern 62a and may pass through the substrate SUB in the vertical direction Z. The front side pattern M1a may be electrically connected to the backside pattern 62a via the first via VA and the through-via THV2 and may be electrically connected to the wiring patterns M2b and M2d via the second vias V1. As such, the source region SS may receive the ground voltage VSS from the backside pattern 62a via the wiring patterns M2b and M2d, the front side pattern M1a, and the through-via THV2.

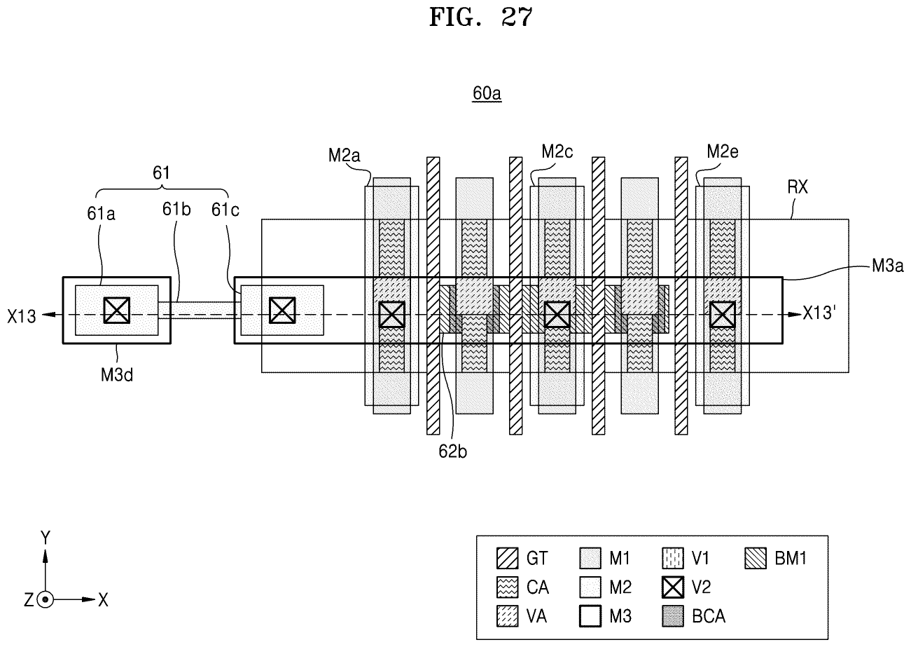

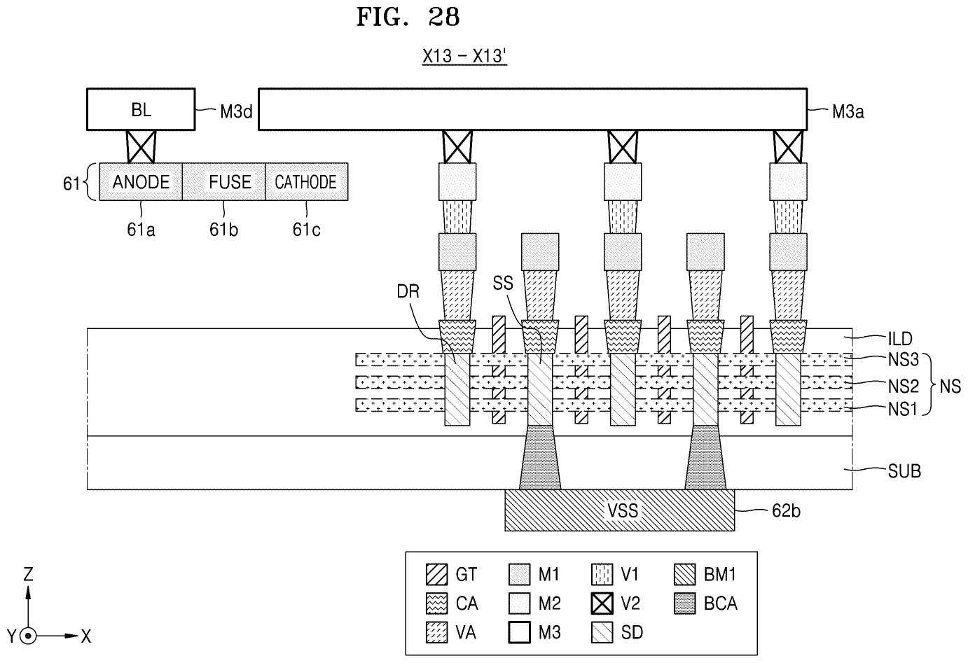

FIG. 27 is a layout of an example of an integrated circuit according to some implementations. FIG. 28 is a cross-sectional view of the integrated circuit taken along line X13-X13′ of FIG. 27 according to some implementations.

In FIGS. 27 and 28, an integrated circuit 60a may correspond to a modified example of the integrated circuit 60 of FIGS. 25 and 26. The integrated circuit 60a may further include the backside contacts BCA as compared with the integrated circuit 60, and the first backside wiring layer BM1 may include the backside pattern 62b. According to some implementations, the e-fuse 61 may receive the bit line BL signal via the FSPDN. According to some implementations, the integrated circuit 60a may electrically connect the e-fuse 61 to the drain region DR of the transistor via the FSPDN. According to some implementations, the source region SS of the transistor may receive the ground voltage VSS via the BSPDN. The backside pattern 62b may receive the ground voltage VSS, and the backside contacts BCA may be arranged on the backside pattern 62b and may pass through the substrate SUB in the vertical direction Z. The source region SS may receive the ground voltage VSS from the backside pattern 62b via the backside contacts BCA.

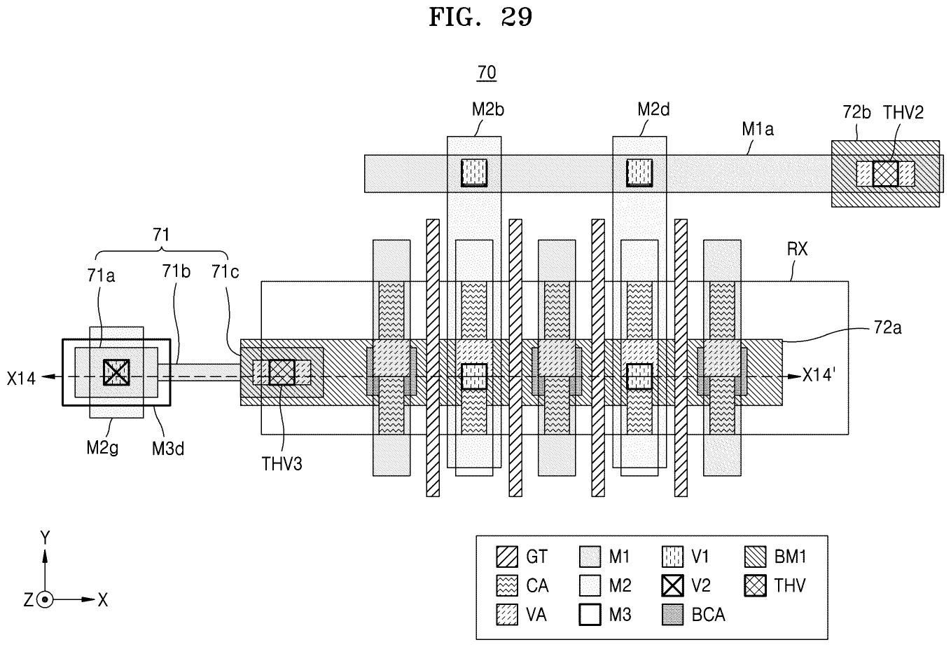

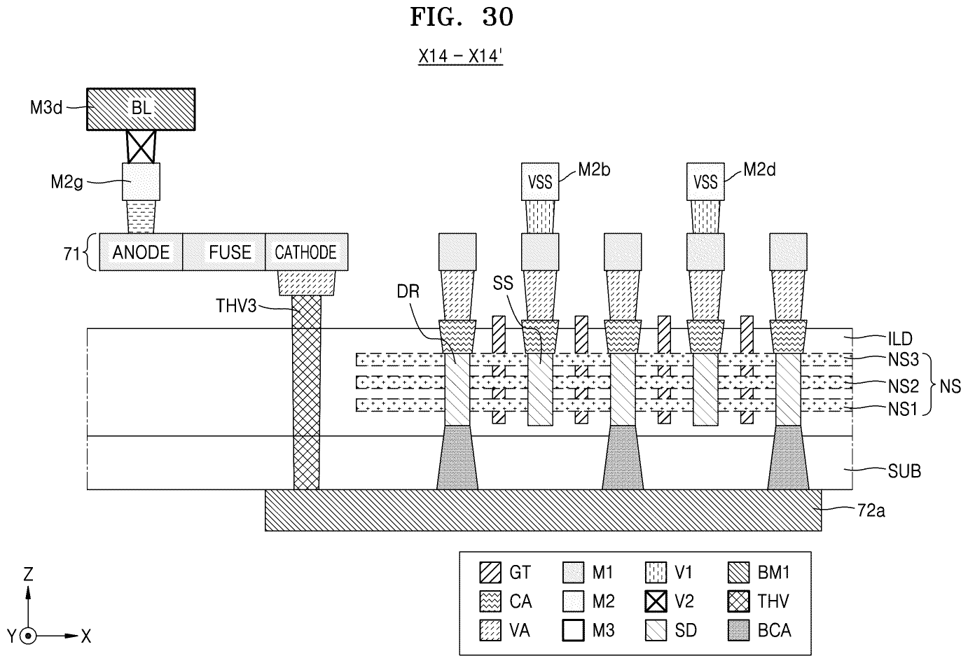

FIG. 29 is a diagram showing a layout of an example of an integrated circuit according to some implementations. FIG. 30 is a cross-sectional view of the integrated circuit taken along line X14-X14′ of FIG. 29 according to some implementations.

In FIGS. 29 and 30, an integrated circuit 70 may include the active region RX, the gate lines GT, the contacts CA, the first to third vias VA, V1, and V2, and the first to third front side wiring layers M1, M2, and M3, the first backside wiring layer BM1, the through-via THV, and the backside contacts BCA. The through via THV may include through-vias THV2 and THV3. An e-fuse 71 may include a first terminal 71a, a link 71b, and a second terminal 71c and may be arranged in the first front side wiring layer M1. The first front side wiring layer M1 may further include the front side pattern M1a extending in the first direction X. The second front side wiring layer M2 may include wiring patterns M2b, M2d, and M2g that each extend in the second direction Y and are spaced apart from one another in the first direction X. The third front side wiring layer M3 may include a wiring line M3d. The first backside wiring layer BM1 may include backside patterns 72a and 72b.

In some implementations, the e-fuse 71 may receive the bit line BL signal via the FSPDN. For example, the first terminal 71a may be connected to the wiring line M3d via the second via V1, the wiring pattern M2g, and the third via V2, and the wiring line M3d may be electrically connected to the bit line BL. As such, the first terminal 71a may be electrically connected to the bit line BL via the wiring line M3d and may receive the bit line BL signal.

In some implementations, the integrated circuit 70 may electrically connect the e-fuse 71 to the drain region DR of the transistor via the BSPDN. For example, the second terminal 71c may be connected to the backside pattern 72a via the first via VA and the through-via THV3, and the backside pattern 72a may be connected to the drain regions DR of the transistor via the backside contacts BCA. As described above, the second terminal 71c may be electrically connected to the drain regions DR via the first via VA, the through-via THV3, the backside pattern 72a, and the backside contacts BCA.

In some implementations, the source region SS of the transistor may receive the ground voltage VSS via the BSPDN. For example, the backside pattern 72b may receive the ground voltage VSS and may be electrically connected to the front side pattern M1a via the through-via THV2 and the first via VA. The front side pattern M1a may be electrically connected to the wiring patterns M2b and M2d via the second vias V1. As such, the source regions SS of the transistor may receive the ground voltage VSS from the backside pattern 72b via the first and second vias VA and V1, the first and second front side wiring layers M1 and M2, and the through-via THV2.

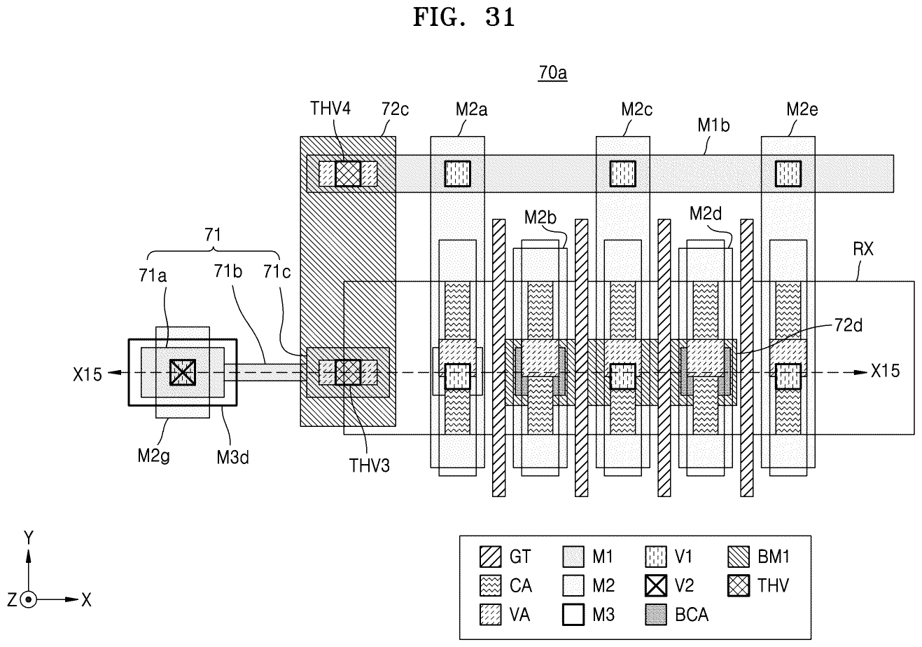

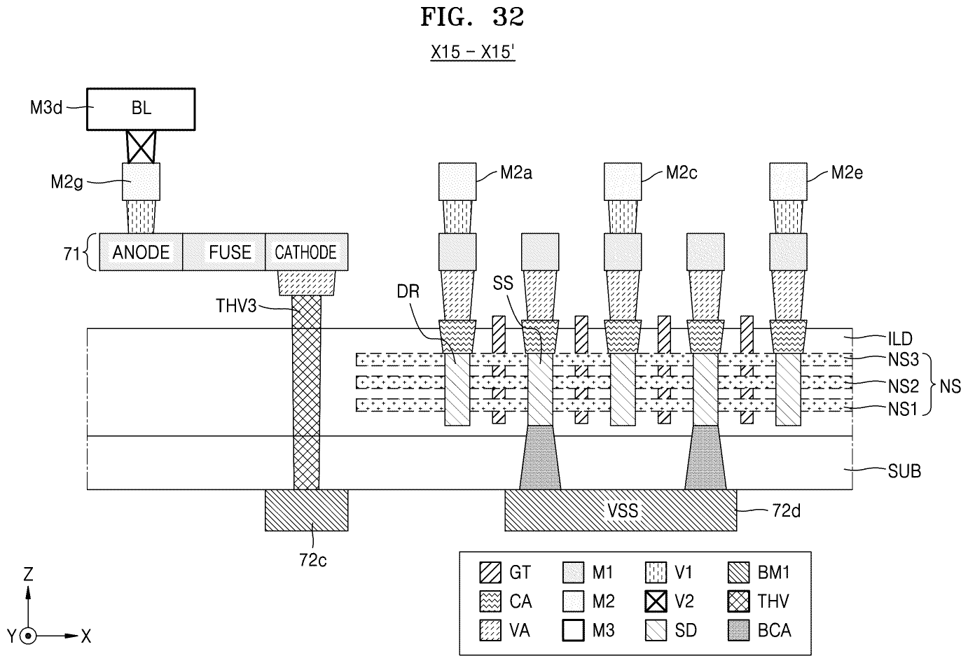

FIG. 31 is a layout of an example of an integrated circuit according to some implementations. FIG. 32 is a cross-sectional view of the integrated circuit taken along line X15-X15′ of FIG. 31 according to some implementations.

In FIGS. 31 and 32, an integrated circuit 70a may correspond to a modified example of the integrated circuit 70 of FIGS. 29 and 30. The through-via THV may include through-vias THV3 and THV4. The first front side wiring layer M1 may further include the front side pattern M1b extending in the first direction X, the second front side wiring layer M2 may include wiring patterns M2a, M2c, M2e, and M2g, and the third front side wiring layer M3 may include the wiring line M3d. The first backside wiring layer BM1 may include backside patterns 72c and 72d.

According to some implementations, the e-fuse 71 may receive the bit line BL signal via the FSPDN, and the integrated circuit 70a may electrically connect the e-fuse 71 to the drain region DR of the transistor via the FSPDN and BSPDN. For example, the backside pattern 72c and the front side pattern M1b may be used as interconnections for connecting the e-fuse 71 to the transistor. In detail, the second terminal 71c may be connected to the backside pattern 72c via the first via VA and the through-via THV3, and the backside pattern 72c may be connected to the front side pattern M1b via the through-via THV4 and the first via VA. The front side pattern M1b may be connected to the wiring patterns M2a, M2c, and M2e via the second vias V2. As described above, the second terminal 71c may be electrically connected to the drain regions DR of the transistor via the first and second vias VA and V1, the through-vias THV3 and THV4, the backside pattern 72c, the first and second front side wiring layers M1 and M2, and the contacts CA.

According to some implementations, the source region SS of the transistor may receive the ground voltage VSS via the BSPDN. For example, the backside pattern 72d may receive the ground voltage VSS and may be electrically connected to the source regions SS of the transistor via the backside contacts BCA. As such, the source regions SS may receive the ground voltage VSS from the backside pattern 72d via the backside contacts BCA.

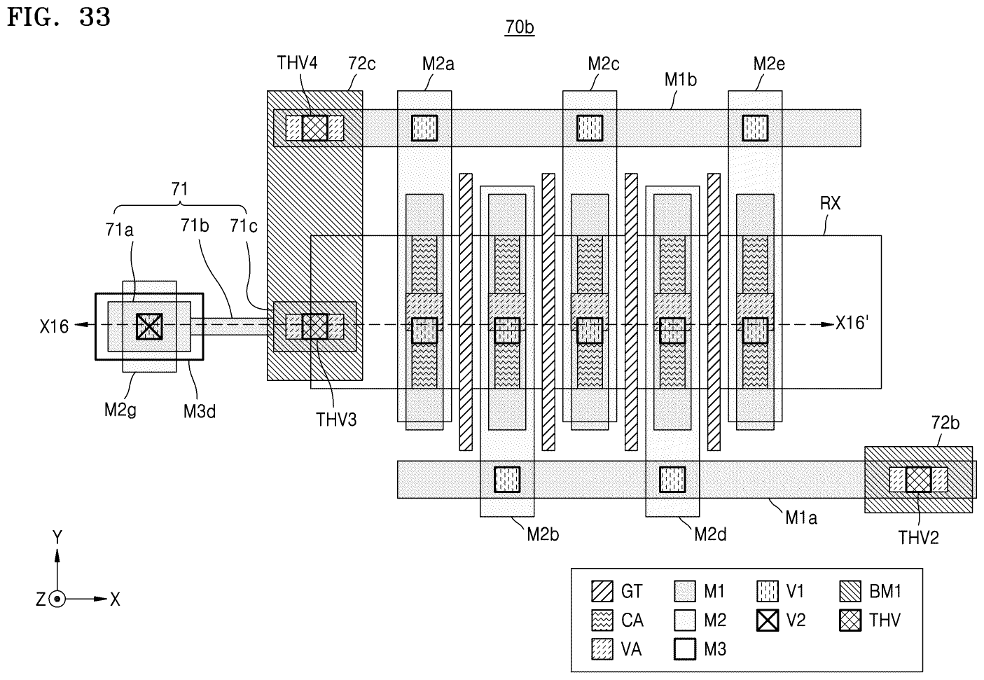

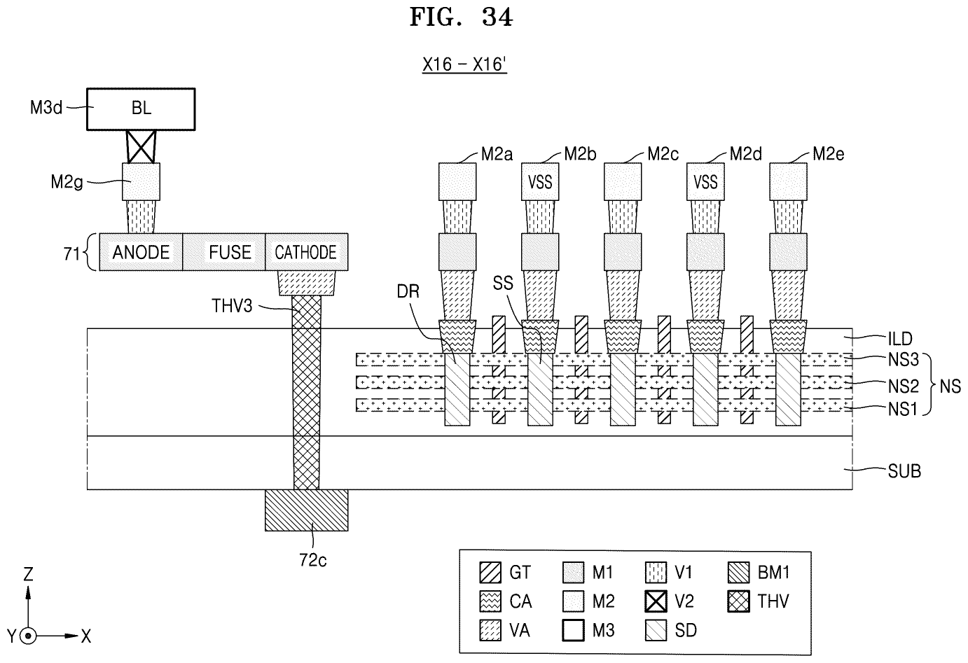

FIG. 33 is a diagram showing a layout of an example of an integrated circuit according to some implementations. FIG. 34 is a cross-sectional view of the integrated circuit taken along line X16-X16′ of FIG. 33 according to some implementations.

In FIGS. 33 and 34, an integrated circuit 70b may correspond to a modified example of the integrated circuit 70b shown in FIGS. 31 and 32. The through via THV may include through-vias THV2, THV3, and THV4. The first front side wiring layer M1 may further include front side patterns M1a and M1b respectively extending in the first direction X, the second front side wiring layer M2 may include wiring patterns M2a to M2e, and M2g, and the third front side wiring layer M3 may include a wiring line M3d. The first backside wiring layer BM1 may include backside patterns 72b and 72c.

According to some implementations, the e-fuse 71 may receive the bit line BL signal via the FSPDN, and the integrated circuit 70b may electrically connect the e-fuse 71 to the drain region DR of the transistor via the FSPDN and BSPDN. According to some implementations, the source region SS of the transistor may receive the ground voltage VSS via the FSPDN and the BSPDN. For example, the backside pattern 72b may receive the ground voltage VSS and may be electrically connected to the front side pattern M1a via the through-via THV2 and the first via VA. The front side pattern M1a may be electrically connected to the wiring patterns M2b and M2d via the second vias V1. As such, the source regions SS may receive the ground voltage VSS from the backside pattern 72b via the first and second front side wiring layers M1 and M2, the first and second vias VA and V1, and the through-via THV2.

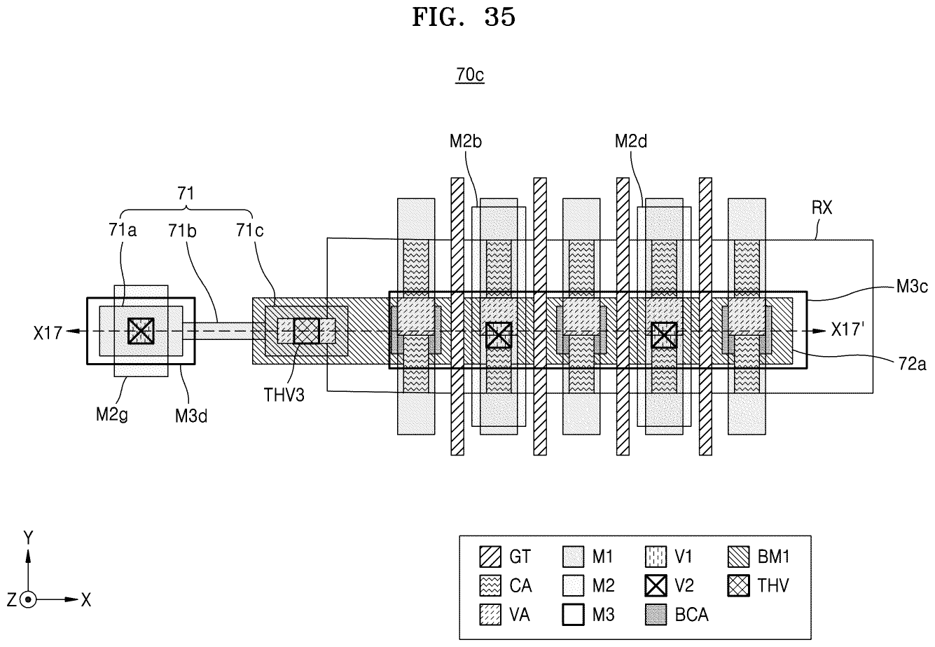

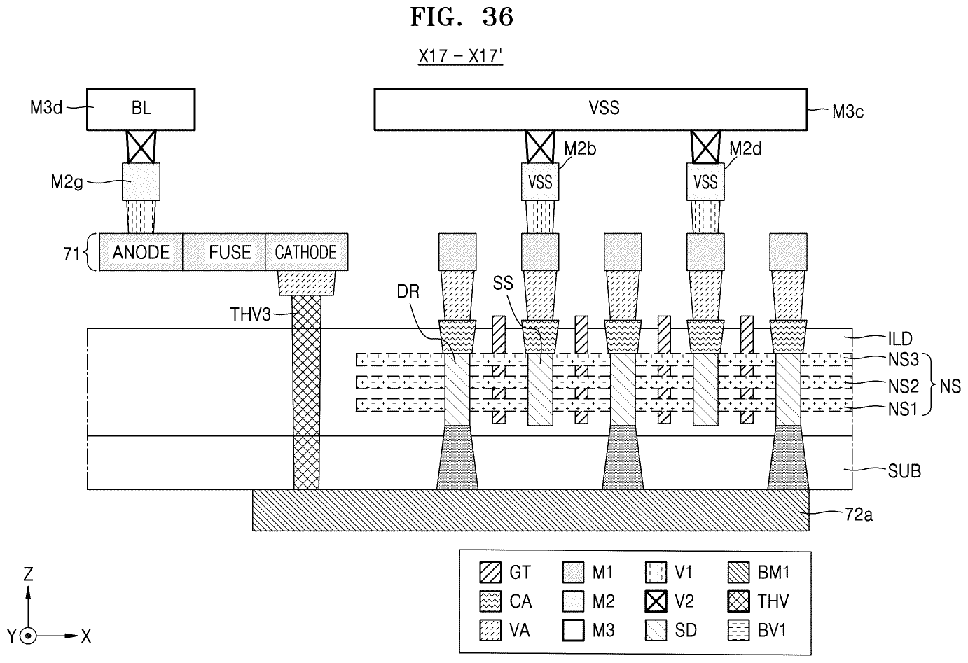

FIG. 35 is a diagram showing a layout of an example of an integrated circuit according to some implementations. FIG. 36 is a cross-sectional view of the integrated circuit taken along line X17-X17′ of FIG. 35 according to some implementations.

In FIGS. 35 and 36, an integrated circuit 70c may correspond to a modified example of the integrated circuit 70 shown in FIGS. 29 and 30. The through-via THV may include a through-via THV3. The second front side wiring layer M2 may include wiring patterns M2b, M2d, and M2g, and the third front side wiring layer M3 may include the wiring lines M3c and M3d. The first backside wiring layer BM1 may include a backside pattern 72a.

According to some implementations, the e-fuse 71 may receive the bit line BL signal via the FSPDN, and the integrated circuit 70c may electrically connect the e-fuse 71 to the drain region DR of the transistor via the BSPDN. According to some implementations, the source region SS of the transistor may receive the ground voltage VSS via the FSPDN. For example, the wiring line M3c may receive the ground voltage VSS and may be electrically connected to the wiring patterns M2b and M2d via the third vias V2. As such, the source regions SS may receive the ground voltage VSS from the wiring line M3c via the first to third front side wiring layers M1, M2, and M3, the first to third vias VA, V1, and V2, and the contacts CA.

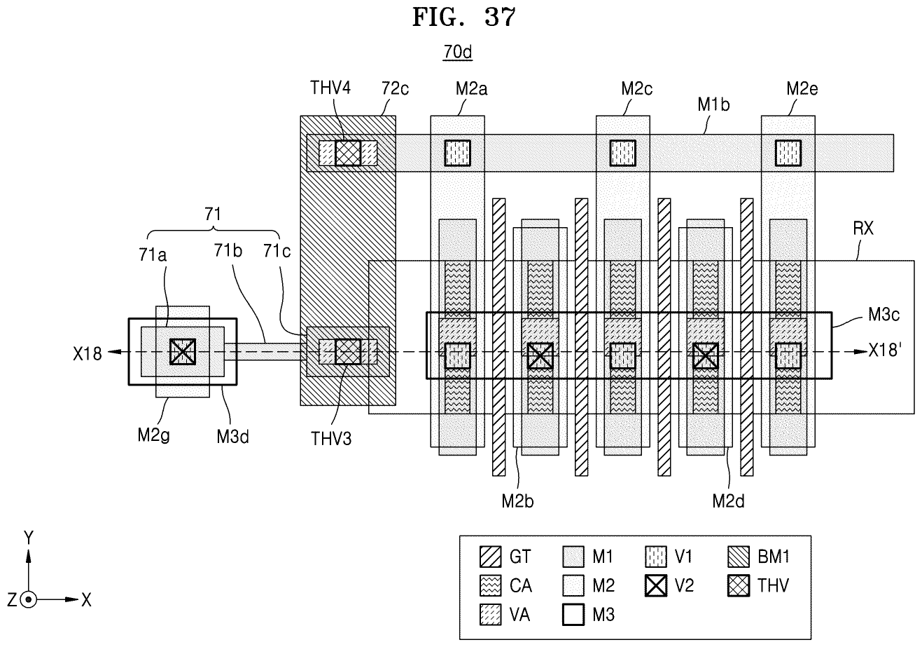

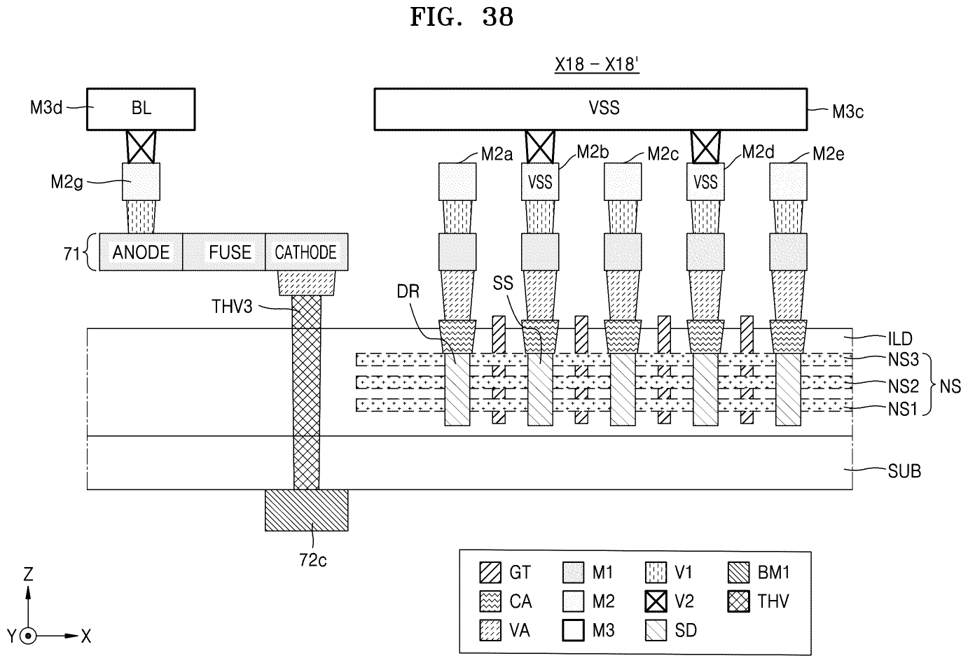

FIG. 37 is a diagram showing a layout of an example of an integrated circuit according to some implementations. FIG. 38 is a cross-sectional view of the integrated circuit taken along line X18-X18′ of FIG. 37 according to some implementations.

In FIGS. 37 and 38, an integrated circuit 70d may correspond to a modified example of the integrated circuit 70 shown in FIGS. 29 and 30. The through-via THV may include through-vias THV3 and THV4. The second front side wiring layer M2 may include wiring patterns M2b, M2d, and M2g, and the third front side wiring layer M3 may include the wiring lines M3c and M3d. The first backside wiring layer BM1 may include a backside pattern 72c.

According to some implementations, the e-fuse 71 may receive the bit line BL signal via the FSPDN, and the integrated circuit 70d may electrically connect the e-fuse 71 to the drain region DR of the transistor via the FSPDN and BSPDN. For example, the second terminal 71c may be connected to the backside pattern 72c via the first via VA and the through-via THV3, and the backside pattern 72c may be connected to the front side pattern M1b via the through-via THV4 and the first via VA. The front side pattern M1b may be connected to the wiring patterns M2a, M2c, and M2e via the second vias V2. As described above, the second terminal 71c may be electrically connected to the drain regions DR of the transistor via the first and second vias VA and V1, the through-vias THV3 and THV4, the backside pattern 72c, the first and second front side wiring layers M1 and M2, and the contacts CA. According to some implementations, the source region SS of the transistor may receive the ground voltage VSS via the FSPDN.

FIGS. 39A to 39D are diagrams showing examples of elements according to some implementations. For example, FIG. 39A shows a FinFET 80a, FIG. 39B shows a gate-all-around field effect transistor (GAAFET) 80b, FIG. 39C shows a multi-bridge channel field effect transistor (MBCFET) 80c, and FIG. 39D shows a vertical field effect transistor (VFET) 80d. For convenience of illustration, FIGS. 39A to 39C show a state in which one of two source/drain regions is removed, and FIG. 39D shows a cross-section of the VFET 80d taken by a plane that is parallel to a plane in the second direction Y and the vertical direction Z and passes through a channel CH of the VFET 80d.

In FIG. 39A, the FinFET 80a may be formed by a fin-shaped active pattern extending in the first direction X between device isolation layers STI and a gate G extending in the second direction Y. The source/drains S/D may be respectively formed on both sides of the gate G, and accordingly, the source and the drain may be spaced apart from each other in the first direction X. An insulation layer may be formed between the channels CH and the gate G. In some implementations, the FinFET 80a may be formed by a plurality of active patterns that are spaced apart from one another in the second direction Y and the gate G.

In FIG. 39B, the GAAFET 80b may be formed by active patterns that are spaced apart from each other in the vertical direction Z and extend in the first direction X, that is, nanowires, and the gate G extending in the second direction Y. The source/drains S/D may be respectively formed on both sides of the gate G, and accordingly, the source and the drain may be spaced apart from each other in the first direction X. An insulation layer may be formed between the channels CH and the gate G. The number of nanowires included in the GAAFET 80b is not limited by the example shown in FIG. 39B.

In FIG. 39C, the MBCFET 80c may be formed by the active patterns that are spaced apart from one another in the vertical direction Z and extend in the first direction X, that is, nano-sheets, and the gate G extending in the second direction Y. The source/drains S/D may be respectively formed on both sides of the gate G, and accordingly, the source and the drain may be spaced apart from each other in the first direction X. An insulation layer may be formed between the channels CH and the gate G. The number of nano-sheets included in the MBCFET 80c is not limited to the example shown in FIG. 39C.

In FIG. 39D, the VFET 80d may include top source/drain T_S/D and bottom source/drain B_S/D that are spaced apart from each other in the vertical direction Z with the channel CH disposed therebetween. The VFET 80d may include the gate G surrounding the circumference of the channel CH between the top source/drain T_S/D and the bottom source/drain B_S/D. An insulation layer may be formed between the channel CH and the gate G.

However, the transistor according to some implementations is not limited to the above structure. For example, the integrated circuit may include a ForkFET having a structure in which an N-type transistor and a P-type transistor are close to each other by separating nano-sheets for the P-type transistor and nano-sheets for the N-type transistor by means of a dielectric wall. Also, the integrated circuit may include a bipolar-junction transistor, as well as the FET such as complementary FET (CFET), negative capacitance FET (NCFET), carbon-nanotube FET (CNT FET), etc.

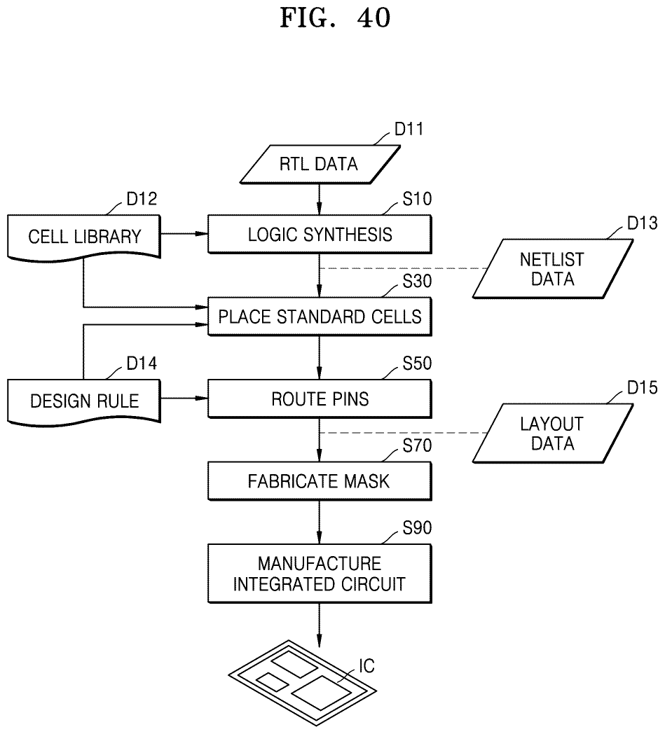

FIG. 40 is a flowchart illustrating an example of a method of manufacturing an integrated circuit, according to some implementations. In FIG. 40, a method of manufacturing an integrated circuit IC includes standard cells and may include a plurality of operations S10, S30, S50, S70, and S90. A cell library (or standard cell library) D12 may include information about standard cells, e.g., functions, characteristics, layout, etc. A design rule D14 may include regulations that the layout of the integrated circuit IC has to comply with. For example, the design rule D14 may include regulations about a space between patterns in the same layer, a minimum width of the pattern, a routing direction of a wiring layer, etc.

In operation S10, a logic synthesis operation for producing netlist data D13 from register transfer level (RTL) data D11 may be performed. For example, a semiconductor design tool (e.g., logic synthesis tool) may perform logic synthesis with reference to a cell library D12 from the RTL data D11 that is written in a hardware description language (HDL) such as Very High Speed Integrated Circuit (VHSIC) hardware description language (VHDL) or Verilog, thereby producing the netlist data D13 including a bitstream or a netlist. The netlist data D13 may correspond to an input of place and routing that is described below.

In operation S30, standard cells may be placed. For example, the semiconductor design tool (e.g., P&R tool) may place the standard cells used in the netlist data D13, with reference to the cell library D12. In some implementations, the semiconductor design tool may place the standard cells on a row extending in the X-axis direction or Y-axis direction, and the placed standard cells may receive the supply of power from the power rail extending along the boundaries of the rows.

In operation S50, pins of the standard cells may be routed. For example, the semiconductor design tool may generate interconnections for electrically connecting output pins to input pins of the arranged standard cells and generate layout data D15 defining the arranged standard cells and generated interconnections. The interconnection may include vias in the via layer and/or patterns of the wiring layers. The wiring layers may include a front side wiring layer arranged on the upper portion of the front surface of the substrate and a backside wiring layer arranged on the rear surface of the substrate. The layout data D15 may have a format, e.g., GDSII, and may include geometrical information about cells and interconnections. The semiconductor design tool may refer to the design rule D14 during routing the pins of the cells. The layout data D15 may correspond to the output from the place and routing. Operation S50 solely or operations S30 and S50 may be referred to as a method of designing an integrated circuit.

As shown in FIGS. 1 to 38, the integrated circuit may implement the e-fuse bit cell by using the front wiring lines and the rear wiring lines. In some implementations, the e-fuse included in the e-fuse bit cell may be arranged on the backside wiring layer. In some implementations, the wiring for connection between the e-fuse and the transistor included in the e-fuse bit cell may be implemented by the front side wiring layer and/or the backside wiring layer. In some implementation, a power rail for providing the supply voltage to the transistor included in the e-fuse bit cell may be implemented by the front side wiring layer and/or the backside wiring layer. In some implementations, a bit line connected to the e-fuse included in the e-fuse bit cell may be implemented by the front side wiring layer and/or the backside wiring layer.

According to some implementations, an area for implementing the e-fuse bit cell may be reduced, and IR drop of the signals applied to the e-fuse bit cell may be reduced. For example, the e-fuse bit cell may improve the operating speed on the e-fuse bit cell by reducing the parasitic resistance and parasitic capacitance by reducing the bit line signals, supply voltage, and/or fuse source voltage from the front side wiring layer and the backside wiring layer, and thereby improving the performance of the integrated circuit.

Also, according to some implementations, the integrated circuit may reduce the routing complexity of the front side wiring layer by using the rear wiring lines included in the backside wiring layer and may improve the PPA of the integrated circuit. Also, the IR drop of the signal applied to the front wiring lines may be further reduced by increasing the widths of the front wiring lines included in the front side wiring layer arranged above the e-fuse bit cell. Moreover, the integrated circuit may further improve the PPA of the integrated circuit by having a DBC structure, in which the source/drain regions of the transistor are directly connected to the backside wiring line of the backside wiring layer.

In operation S70, an operation of fabricating a mask may be performed. For example, an optical proximity correction (OPC) for correcting a distortion such as refraction caused by the characteristics of light in a photolithography may be applied to the layout data D15. Patterns on the mask may be defined in order to form the patterns arranged on the plurality of layers based on the data to which the OPC is applied, and at least one mask for forming the patterns in each of the plurality of layers may be fabricated.

In operation S90, the operation of manufacturing the integrated circuit IC may be performed. For example, the plurality of layers are patterned by using at least one mask fabricated in operation S70, and then, the integrated circuit IC may be manufactured. A front-end-of-line (FEOL) may include, for example, an operation of planarizing and cleaning a wafer, an operation of forming a trench, an operation of forming a well, an operation of forming gate lines, and an operation of forming source and drain. Through the FEOL, individual elements, e.g., a transistor, a capacitor, a resistor, etc. may be formed on the substrate. Also, a back-end-of-line (BEOL) may include, for example, a silicidation of a gate, source, and drain region, an operation of adding a dielectric substance, a planarization operation, an operation of forming a hole, an operation of adding a metal layer, an operation of forming vias, and an operation of forming a passivation layer, etc. Through the BEOL, the individual elements, e.g., a transistor, a capacitor, a resistor, etc. may be connected to one another. In some implementations, a middle-of-line (MOL) may be performed between the FEOL and BEOL, and contacts may be formed on the individual elements. Next, the integrated circuit IC may be packaged in the semiconductor package, and may be used as a component in various applications.

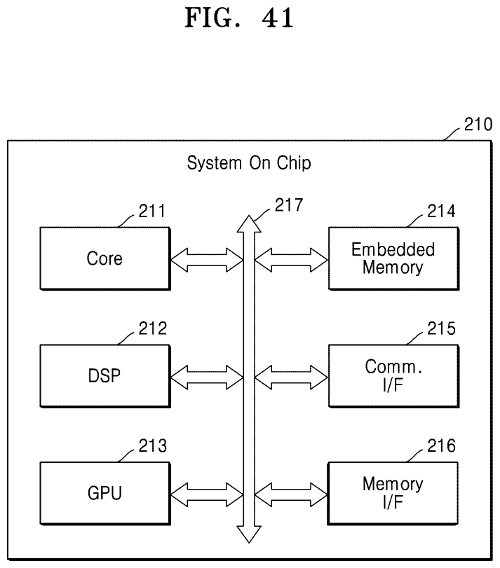

FIG. 41 is a block diagram of an example of a system-on-chip according to some implementations. In FIG. 41, a system-on-chip (SoC) 210 may denote an integrated circuit on which components of a computing system or another electronic systems are integrated. For example, an application processor (AP) as an example of the SoC 210 may include a processor and components for other functions. The SoC 210 may include a core 211, a digital signal processor (DSP) 212, a graphic processing unit (GPU) 213, an internal memory 214, a communication interface 215, and a memory interface 216. The components of the SoC 210 may communicate with one another via a bus 217.

The core 211 may process instructions and may control operations of the elements included in the SoC 210. For example, the core 211 may drive an operating system and may execute applications on the operating system by processing a series of instructions. The DSP 212 may generate useful data by processing a digital signal, e.g., a digital signal provided from the communication interface 215. The GPU 213 may generate data for an image output through a display apparatus from image data provided from the internal memory 214 or the memory interface 216 or may encode image data. In some implementations, the IC described above with reference to the drawings may be included in the core 211, the DSP 212, the GPU 213, and/or the internal memory 214.

The internal memory 214 may store data that is required for the core 211, the DSP 212, and the GPU 213 to operate. The communication interface 215 may provide a communication network or an interface for one-to-one communication. The memory interface 216 may provide an interface about an external memory of the SoC 210, e.g., DRAM, flash memory, etc.

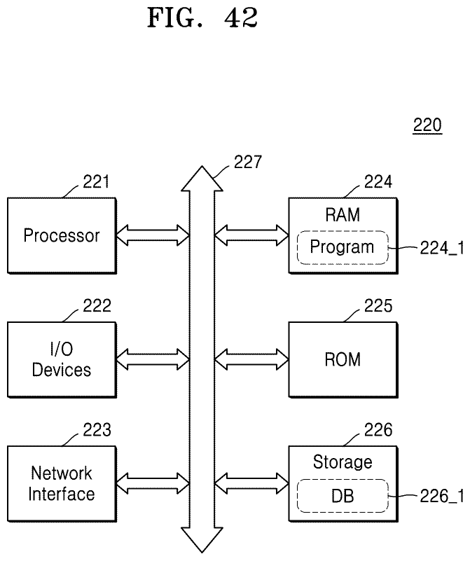

FIG. 42 is a block diagram of an example of a computing system including a memory for storing a program according to some implementations. In FIG. 42, at least some of the method of designing the IC, e.g., the operations in the flowchart described above, according to some implementations, may be executed in a computing system 220. The computing system 220 may include a processor 221, I/O devices 222, a network interface 223, a random access memory (RAM) 224, a read only memory (ROM) 225, and a storage 226. The processor 221, the I/O devices 222, the network interface 223, the RAM 224, the ROM 225, and the storage 226 may be connected to a bus 227 and may communicate with each other via the bus 227.

The processor 221 may be referred to as a processing unit and may include at least one core capable of executing arbitrary instruction sets, e.g., a microprocessor, an AP, a DSP, and a GPU. For example, the processor 221 may be configured to access the memory, that is, the RAM 224 or the ROM 225, via the bus 227, and to execute instructions stored in the RAM 224 or ROM 225. The RAM 224 may store a program 224_1 for the method of designing the IC according to some implementations or at least a portion thereof, and the program 224_1 may allow the processor 221 to execute at least some of the method of designing the IC, e.g., the operations included in the method illustrated with reference to FIG. 40.

Data stored in the storage 226 may not be erased when the computing system 220 is out of power supply. The storage 226 may store the program 224_1 according to some implementations, and before the program 224_1 is executed by the processor 221, the program 224_1 or at least a part thereof may be loaded from the storage 226 to the RAM 224. Alternatively, the storage 226 may store a file that is made by using a program language, and the program 224_1 generated from the file by a compiler, etc., or at least a part of the program 224_1 may be loaded from the file to the RAM 224. Also, the storage 226 may store a database (DB) 226_1, and the database 226_1 may include information required for designing the integrated circuit, e.g., information about designed blocks, the cell library D12 and/or design rule D14 shown in FIG. 40.

The storage 226 may also store data to be processed/has been processed by the processor 221. That is, the processor 221 may, according to the program 224_1, generate data by processing the data stored in the storage 226 and store the generated data in the storage 226. For example, the storage 226 may store the RTL data D11, the netlist data D13, or the layout data D15 shown in FIG. 40.

The I/O devices 222 may include an input device such as a keyboard, a pointing device, etc. and may include an output device such as a display apparatus, a printer, etc. For example, by using the I/O devices 222, a user may trigger execution of the program 224_1 by using the processor 221, input the RTL data D11 and/or the netlist data D13 shown in FIG. 40, and confirm the layout data D15 of FIG. 40. The network interface 223 may provide access to a network outside the computing system 220. For example, the network may include a plurality of computing systems and communication links, and the communication links may include wired links, optical links, wireless links, or links of other arbitrary forms.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

1. An integrated circuit comprising:
a first backside wiring layer on a backside of a substrate;
an electronic fuse (e-fuse) bit cell including an e-fuse, a transistor on a front side of the substrate and a first backside contact configured to pass through the substrate in a vertical direction and electrically connecting the e-fuse to the transistor,
wherein the e-fuse comprises:
a first terminal electrically connected to a bit line;
a second terminal electrically connected to the first backside contact; and
a link between the first terminal and the second terminal, and
wherein the first terminal, the second terminal, and the link are included in the first backside wiring layer.

2. The integrated circuit of claim 1, further comprising:
a second backside wiring layer below the first backside wiring layer; and
a backside via configured to extend between the first backside wiring layer and the second backside wiring layer in the vertical direction,
wherein the first terminal is electrically connected to the bit line via the backside via and the second backside wiring layer.

3. The integrated circuit of claim 1, further comprising:
a backside wiring layer between the backside of the substrate and the first backside wiring layer; and
a backside via that extends in the vertical direction between the backside wiring layer and the first backside wiring layer,
wherein the second terminal is electrically connected to the first backside contact via the backside via and the backside wiring layer.

4. The integrated circuit of claim 1, further comprising a front side wiring layer above the front side of the substrate,
wherein a source of the transistor is configured to receive a supply voltage via the front side wiring layer.

5. The integrated circuit of claim 1,
wherein the first backside wiring layer further comprises a first backside pattern configured to receive a supply voltage,
wherein the integrated circuit further comprises a second backside contact on the first backside pattern and passing through the substrate in the vertical direction, and
wherein a source of the transistor is configured to receive the supply voltage via the second backside contact and the first backside pattern.

6. The integrated circuit of claim 5,
wherein the first backside wiring layer further comprises a second backside pattern connected to the first backside contact,
wherein the integrated circuit further comprises:
a second backside wiring layer below the first backside wiring layer;
a first backside via configured to extend in the vertical direction between the second terminal and the second backside wiring layer; and
a second backside via configured to extend in the vertical direction between the second backside pattern and the second backside wiring layer, and
wherein the second terminal is electrically connected to the first backside contact via the first backside via, the second backside wiring layer, the second backside via, and the second backside pattern.

7. An integrated circuit comprising:
a first front side wiring layer above a front side of a substrate;
a backside wiring layer on a backside of the substrate and including a first backside pattern;
a first through-via on the first backside pattern and configured to pass through the substrate in a vertical direction; and
an e-fuse bit cell including an e-fuse and a transistor on the front side of the substrate,
wherein the e-fuse comprises:
a first terminal electrically connected to the first through-via and electrically connected to a bit line via the first through-via and the first backside pattern;
a second terminal electrically connected to the transistor; and
a link between the first terminal and the second terminal, and
wherein the first terminal, the second terminal, and the link are included in the first front side wiring layer.

8. The integrated circuit of claim 7,
wherein the backside wiring layer further comprises a second backside pattern configured to receive a supply voltage, and
wherein the integrated circuit further comprises a first backside contact configured to pass through the substrate in the vertical direction and electrically connect the second backside pattern to a source of the transistor.

9. The integrated circuit of claim 7,
wherein the first front side wiring layer further comprises a front side pattern above a source of the transistor, and
wherein the source of the transistor is configured to receive a supply voltage from the front side pattern.

10. The integrated circuit of claim 7,
wherein the first front side wiring layer further comprises a first front side pattern above a source of the transistor and a second front side pattern,
wherein the backside wiring layer further comprises a third backside pattern configured to receive a supply voltage,
wherein the integrated circuit further comprises:
a second through-via on the third backside pattern, the second through-via configured to pass through the substrate in the vertical direction and electrically connect the third backside pattern to the second front side pattern; and
a second front side wiring layer above the first front side wiring layer and electrically connecting the first front side pattern to the second front side pattern, and
wherein the source of the transistor is configured to receive the supply voltage via the first front side pattern, the second front side wiring layer, the second front side pattern, the second through-via, and the third backside pattern.

11. The integrated circuit of claim 7,
wherein the first front side wiring layer further comprises a front side pattern above a drain of the transistor,
wherein the integrated circuit further comprises a second front side wiring layer above the first front side wiring layer, and
wherein the drain of the transistor is electrically connected to the second terminal via the second front side wiring layer and the front side pattern.

12. The integrated circuit of claim 7,
wherein the backside wiring layer further comprises a fourth backside pattern, and
wherein the integrated circuit further comprises:
a third through-via configured to pass through the substrate in the vertical direction and electrically connect the fourth backside pattern to the second terminal; and
a second backside contact on the fourth backside pattern and configured to electrically connect the fourth backside pattern to a drain of the transistor.

13. The integrated circuit of claim 7,
wherein the first front side wiring layer further comprises a front side pattern,
wherein the backside wiring layer further includes a fifth backside pattern,
wherein the integrated circuit further comprises:
a third through-via configured to pass through the substrate in the vertical direction and electrically connect the fifth backside pattern to the second terminal; and
a fourth through-via configured to pass through the substrate in the vertical direction and electrically connect the fifth backside pattern to the front side pattern, and
wherein a drain of the transistor is electrically connected to the second terminal via the front side pattern, the third through-via, the fifth backside pattern, and the fourth through-via.

14-17. (canceled)

18. An integrated circuit comprising:
a first front side wiring layer above a front side of a substrate;
a backside wiring layer on a backside of the substrate and including a first backside pattern;
a first through-via arranged on the first backside pattern and passing through the substrate in a vertical direction; and
an e-fuse bit cell including an e-fuse and a transistor arranged on the front side of the substrate,
wherein the e-fuse comprises:
a first terminal electrically connected to a bit line;
a second terminal electrically connected to the transistor via the first backside pattern and the first through-via; and
a link between the first terminal and the second terminal, and
wherein the first terminal, the second terminal, and the link are included in the first front side wiring layer.

19. The integrated circuit of claim 18,
wherein the backside wiring layer further includes a second backside pattern,
wherein the integrated circuit further comprises:
a second through-via on the second backside pattern and passing through the substrate in the vertical direction; and
a backside contact on the first backside pattern,
wherein a source of the transistor is configured to receive a supply voltage via the second backside pattern and the second through-via, and
wherein a drain of the transistor is electrically connected to the second terminal via the backside contact, the first backside pattern, and the first through-via.

20. The integrated circuit of claim 18,
wherein the backside wiring layer further comprises a third backside pattern, and
wherein the integrated circuit further comprises:
a third through-via on the first backside pattern and passing through the substrate in the vertical direction; and
a backside contact on the third backside pattern,
wherein a source of the transistor is configured to receive a supply voltage via the third backside pattern and the backside contact, and
wherein a drain of the transistor is electrically connected to the second terminal via the third through-via, the first backside pattern, and the first through-via.

21. The integrated circuit of claim 18,
wherein the backside wiring layer further includes a second backside pattern,
wherein the integrated circuit further comprises:
a second through-via on the second backside pattern and passing through the substrate in the vertical direction; and
a third through-via on the first backside pattern and passing through the substrate in the vertical direction,
wherein a source of the transistor is configured to receive a supply voltage via the second backside pattern and the second through-via, and
wherein a drain of the transistor is electrically connected to the second terminal via the first through-via, the first backside pattern, and the third through-via.

22. The integrated circuit of claim 18, further comprising:
a second front side wiring layer above the first front side wiring layer; and
a backside contact on the first backside pattern,
wherein a source of the transistor is configured to receive a supply voltage via the second front side wiring layer, and
wherein a drain of the transistor is electrically connected to the second terminal via the backside contact, the first backside pattern, and the first through-via.

23. The integrated circuit of claim 18, further comprising:
a second front side wiring layer above the first front side wiring layer; and
a third through-via on the first backside pattern and passing through the substrate in a vertical direction,
wherein a source of the transistor is configured to receive a supply voltage via the second front side wiring layer, and
wherein a drain of the transistor is electrically connected to the second terminal via the first and third through-vias and the first backside pattern.
